(19) United States
(12) Patent Application Publication
(10) Pub. No.: US 2025/0318419 A1
(43) Pub. Date: Oct. 9, 2025

(54) DISPLAY DEVICE

(71) Applicant: Samsung Display Co., LTD., Yongin-si (KR)

(72) Inventors: Hoon Gi LEE, Yongin-si (KR); Dong Uk KIM, Yongin-si (KR); Hyun Ho KIM, Yongin-si (KR); Hyoeng Ki KIM, Yongin-si (KR); Hyeon Bum LEE, Yongin-si (KR); Chaun Gi CHOI, Yongin-si (KR)

(21) Appl. No.: 18/932,950

(22) Filed: Oct. 31, 2024

(30) Foreign Application Priority Data
Apr. 8, 2024 (KR) 10-2024-0047080

(51) Int. Cl. H10K 77/10; H10K 59/123; H10K 59/35; H10K 59/38; H10K 59/40; H10K 59/80; H10K 102/00

(52) U.S. Cl. CPC H10K 77/111; H10K 59/123; H10K 59/351; H10K 59/352; H10K 59/38; H10K 59/80515; H10K 59/8791; H10K 59/40; H10K 59/80521; H10K 2102/311

(57) ABSTRACT

A display device includes: a substrate having a folding area foldable with a radius of curvature over a folding axis, and a non-folding area extended from the folding area, and pixels disposed in each of the folding area and the non-folding area on the substrate. Each of the pixels includes a pixel electrode, a light emitting layer disposed on the pixel electrode, and a common electrode disposed on the light emitting layer. The pixel electrode in at least one of the pixels disposed in the folding area is a concave pixel electrode comprising a first portion, which is a bottom portion of the pixel electrode, and a second portion extended from the first portion and inclined in a direction away from the substrate.

This application claims priority to Korean Patent Application No. 10-2024-0047080 filed on Apr. 8, 2024, and all the benefits accruing therefrom under 35 U.S.C. § 119, the content of which in its entirety is herein incorporated by reference.

### BACKGROUND

### 1. Field of the Disclosure

The present disclosure relates to a display device.

### 2. Description of the Related Art

As the information-oriented society evolves, various demands for display devices are ever increasing. For example, display devices are being employed by a variety of electronic devices such as smart phones, digital cameras, laptop computers, navigation devices, and smart televisions.

Display devices may be flat panel display devices such as a liquid-crystal display device, a field emission display device, and a light-emitting display device. Light-emitting display devices include an organic light-emitting display device including organic light-emitting elements, an inorganic light-emitting display device including inorganic light-emitting elements such as inorganic semiconductor, and a micro light-emitting display device including micro light-emitting elements.

An organic light-emitting element may include two opposing electrodes and a light emitting layer interposed therebetween. Electrons and holes supplied from the two electrodes are recombined in the light emitting layer to generate excitons, and the generated excitons relax from the excited state to the ground state so that light can be emitted.

An organic light-emitting display device including organic light-emitting elements requires no separate light source such as a backlight unit, and thus it consumes less power and can be made light and thin, as well as exhibiting high-quality characteristics such as wide viewing angle, high brightness and contrast, and fast response speed. Accordingly, an organic light-emitting display device is attracting attention as the next generation display device.

### SUMMARY

Aspects of the present disclosure provide a display device that can improve the issue of decrease in brightness in a folding area.

It should be noted that objects of the present disclosure are not limited to the above-mentioned object; and other objects of the present disclosure will be apparent to those skilled in the art from the following descriptions.

According to an aspect of the present disclosure, a display device includes a substrate having a folding area foldable with a radius of curvature over a folding axis, and a non-folding area extended from the folding area, and pixels disposed in each of the folding area and the non-folding area on the substrate, wherein each of the pixels includes a pixel electrode, a light emitting layer disposed on the pixel electrode, and a common electrode disposed on the light emitting layer, and wherein the pixel electrode in at least one of the pixels disposed in the folding area is a concave pixel electrode including a first portion, which is a bottom portion of the pixel electrode, and a second portion, which is extended from the first portion and inclined in a direction away from the substrate.

In an embodiment, the folding area may have a width of 0.75πR to 1.25πR from each side of the folding axis to the folding axis in a direction perpendicular to the folding axis, and R may be the radius of curvature in an unfolded state of the folding area.

In an embodiment, the display device may further include a via-layer disposed between the substrate and the pixel electrode, the via-layer may define a groove therein overlapping the concave pixel electrode, and the groove may include a bottom surface and an inclined surface inclined with respect to the bottom surface.

In an embodiment, the groove may include a first groove located at a portion of the folding area, an extension of the bottom surface and the inclined surface of which form a first inclination angle, and a second groove located at another portion of the folding area, an extension line of the bottom surface and the inclined surface of which form a second inclination angle, and the first inclination angle and the second inclination angle may be different from each other.

In an embodiment, an inclination angle between an extension line of the bottom surface and the inclined surface may range from 10 to 40 degrees.

In an embodiment, each of the pixels further may include: a pixel-defining layer covering an edge of the pixel electrode, and wherein the first portion of the concave pixel electrode is disposed on the bottom surface of the groove, and the second portion of the concave pixel electrode is disposed on the inclined surface of the groove and does not overlap the pixel-defining layer in a plan view.

In an embodiment, the concave pixel electrode may further include: a third portion disposed on an upper surface of the via-layer and the inclined surface of the groove and overlapping with the pixel-defining layer in the plan view.

In an embodiment, an area of the second portion of the concave pixel electrode disposed in a portion of the folding area may be different from an area of the second portion of the concave pixel electrode disposed in another portion of the folding area in the plan view.

In an embodiment, the via-layer may include the groove in the folding area but not in the non-folding area.

In an embodiment, the folding area may include a first folding area having a width of πR/8 to πR/4 from each side of the folding axis to the folding axis in a direction perpendicular to the folding axis, and R may be the radius of curvature in an unfolded state of the folding area, and a second folding area other than the first folding area, and a total number of concave pixel electrodes disposed in the second folding area may be greater than a total number of concave pixel electrodes disposed in the first folding area.

In an embodiment, the pixels may include first to third pixels, which emit lights of different colors from each other, one first pixel, one second pixel and two third pixels may form a pixel group, and a total number of pixels having the concave pixel electrodes included in four pixel groups in the first folding area may be equal to 20% to 40% of a total number of pixels included in the four pixel groups in the first folding area.

In an embodiment, the pixels may include first to third pixels, which emit lights of different colors from each other, one first pixel, one second pixel and two third pixels may form a pixel group, and a total number of pixels having the concave pixel electrodes included in four pixel groups in the second folding area may be equal to 45% to 55% of a total number of pixels included in the four pixel groups in the second folding area.

In an embodiment, the pixels may include first to third pixels, which emit lights of different colors, one first pixel, one second pixel and two third pixels may form a pixel group, and a total number of pixels having the concave pixel electrodes included in four pixel groups in the second folding area may be equal to 70% to 80% of a total number of pixels included in the four pixel groups in the second folding area.

In an embodiment, the display device may further include an anti-reflection layer disposed on the common electrode, and the anti-reflection layer may be a color filter layer or a polarizing member.

In an embodiment, the folding area may include: a first folding area having a width of πR/8 to πR/4 from each side of the folding axis to the folding axis in a direction perpendicular to the folding axis, where R may be the radius of curvature in an unfolded state of the folding area; and a second folding area other than the first folding area, and the first groove may be located in the first folding area, and the second groove may be located in the second folding area, and the first inclination angle may be smaller than the second inclination angle.

In an embodiment, the folding area may include: a first folding area having a width of πR/8 to πR/4 from each side of the folding axis to the folding axis in a direction perpendicular to the folding axis, where R may be the radius of curvature in an unfolded state of the folding area; and a second folding area other than the first folding area, the second portion of the concave pixel electrode disposed in the first folding area may have a first area, and the second portion of the concave pixel electrode disposed in the second folding area may have a second area in the plan view, and the first area may be smaller than the second area.

According to an aspect of the present disclosure, a display device is switchable between a folded state and an unfolded state over a folding axis, and the display device includes a substrate having a bendable portion, which is bent in the folded state, and a flat portion, which is extended from the bendable portion and is flat in the folded state, an insulating layer disposed on the substrate, pixel electrodes disposed on the insulating layer, a pixel-defining layer disposed on the pixel electrodes and defining openings therein associated with the pixel electrodes, respectively, light emitting layers arranged to overlap with the openings on the pixel electrodes, and a counter electrode disposed on the light emitting layers, where the pixel electrodes include a first pixel electrode disposed in the bendable portion and a second pixel electrode disposed in the flat portion, and where the first pixel electrode has a concave upper surface toward the substrate.

In an embodiment, an upper surface of the insulating layer may have a shape conforming to the concave upper surface of the first pixel electrode.

In an embodiment, the concave upper surface of the first pixel electrode may include a bottom surface and an inclined surface, and where a first inclination angle between the bottom surface and the inclined surface of the first pixel electrode located in an area of the bendable portion may be different from a second inclination angle between the bottom surface and the inclined surface of the first pixel electrode located in another area of the bendable portion.

In an embodiment, the concave upper surface of the first pixel electrode may include a bottom surface and an inclined surface, and an area of the inclined surface of the first pixel electrode located at a position of the bendable portion in a plan view may be different from an area of the inclined surface of the first pixel electrode located in another position of the bendable portion in the plan view.

According to an embodiment of the present disclosure, it is possible to reduce a brightness difference between a folding area and the non-folding area in a display device by forming a via-layer defining a groove therein in a pixel of the folding area.

In addition, according to an embodiment of the present disclosure, the number of pixels including concave pixel electrodes in a first folding area is different from the number of pixels including concave pixel electrodes in the second folding area in a display device, so that it is possible to reduce a brightness difference even within the folding area as well as between the folding area and the non-folding area.

In addition, according to an embodiment of the present disclosure, in pixels including concave pixel electrodes in a display device, an inclination angle between the bottom surface and the inclined surface of the concave pixel electrode in the first folding area is different from an inclination angle between the bottom surface and the inclined surface of the concave pixel electrode in the second folding area, so that it is possible to reduce brightness differences even within the folding area as well as between the folding area and the non-folding area.

In addition, according to an embodiment of the present disclosure, in pixels including concave pixel electrodes in a display device, the area of the inclined surface of the concave pixel electrode in the first folding area is different from the area of the inclined surface of the concave pixel electrode in the second folding area, so that it is possible to reduce brightness differences even within the folding area as well as between the folding area and the non-folding area.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view of an electronic device according to an embodiment of the present disclosure.

FIG. 2 is a perspective view showing a foldable display device according to an embodiment of the present disclosure when it is folded.

FIG. 3 is a perspective view showing the foldable display device of FIG. 2 when it is unfolded.

FIG. 4 is a perspective view showing a display device included in an electronic device according to an embodiment of the present disclosure.

FIG. 5 is a cross-sectional view of the display device of FIG. 4 seen from the side.

FIG. 6 is a plan view showing a display layer of a display device according to an embodiment of the present disclosure.

FIG. 7 is a plan view showing a touch sensing layer of a display device according to an embodiment of the present disclosure.

FIG. 8 is a plan view showing arrangements of emission areas in a display area of a display device according to an embodiment.

FIG. 9 is a plan view showing a layout of color filters arranged in the display area of FIG. 8.

FIG. 10 is a plan view schematically showing a display panel of a display device according to an embodiment of the present disclosure.

FIG. 11 is a cross-sectional view schematically showing the display panel of the display device according to the embodiment of the present disclosure when it is folded.

FIG. 12 is a cross-sectional view schematically showing the folding area of the display device of FIG. 10.

FIG. 13 is a cross-sectional view showing a pixel in a non-folding area of a display device according to an embodiment of the present disclosure.

FIG. 14 is a cross-sectional view showing a pixel in a folding area of a display device according to an embodiment of the present disclosure.

FIG. 15 is an enlarged view of area A of FIG. 14.

FIG. 16 is a cross-sectional view schematically showing a folding area of a display device according to an embodiment of the present disclosure.

FIG. 17 is a plan view showing an example of pixels in a folding area of a display device according to an embodiment of the present disclosure.

FIG. 18 is a cross-sectional view taken along line Q1-Q1′ of FIG. 17.

FIG. 19 is a plan view showing another example of pixels of a folding area of a display device according to an embodiment of the present disclosure.

FIG. 20 is a plan view showing another example of pixels in a folding area of a display device according to an embodiment of the present disclosure.

FIG. 21 is a plan view showing a pixel of a first folding area of a display device according to an embodiment of the present disclosure.

FIG. 22 is a cross-sectional view taken along line Q2-Q2′ of FIG. 21.

FIG. 23 is a plan view showing a pixel of a second folding area of a display device according to an embodiment of the present disclosure.

FIG. 24 is a cross-sectional view taken along line Q3-Q3′ of FIG. 23.

FIG. 25 is a cross-sectional view showing a pixel of a first folding area of a display device according to an embodiment of the present disclosure.

FIG. 26 is a cross-sectional view showing a pixel of a second folding area of a display device according to an embodiment of the present disclosure.

FIG. 27 is a cross-sectional view schematically showing a display device according to yet another embodiment.

FIG. 28 is a graph showing brightness and the amount of changes in the brightness versus viewing angle of display devices according to Comparative Example and Example.

### DETAILED DESCRIPTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. Hereinafter, embodiments of the present disclosure will be described with reference to the accompanying drawings.

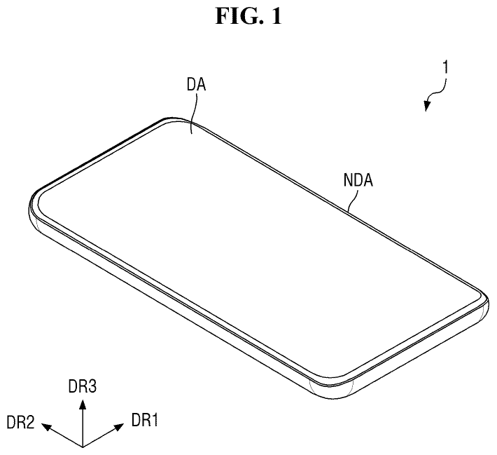

FIG. 1 is a perspective view of an electronic device according to an embodiment of the present disclosure.

Referring to FIG. 1, an electronic device 1 displays a moving image or a still image. The electronic device 1 may refer to any electronic device that provides a display screen. For example, the electronic device 1 may include a television set, a laptop computer, a monitor, an electronic billboard, the Internet of Things devices, a mobile phone, a smart phone, a tablet personal computer (PC), an electronic watch, a smart watch, a watch phone, a head-mounted display device, a mobile communications terminal, an electronic notebook, an electronic book, a portable multimedia player (PMP), a navigation device, a game console and a digital camera, a camcorder, etc.

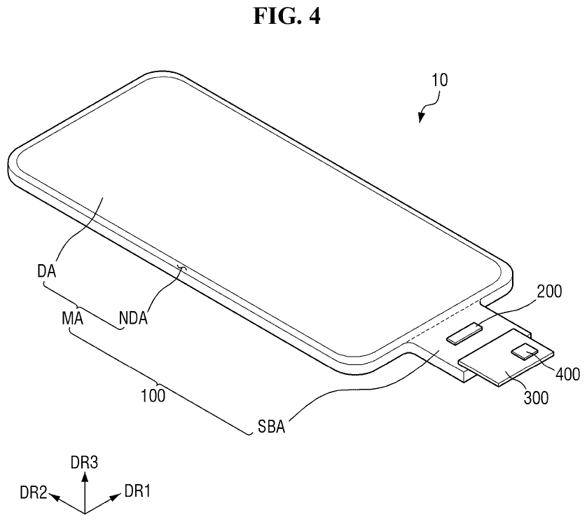

The electronic device 1 may include a display device 10 (see FIG. 4) for providing a display screen. Examples of the display device may include an inorganic light-emitting diode display device, an organic light-emitting display device, a quantum-dot light-emitting display device, a plasma display device, a field emission display device, etc. In the following description, an organic light-emitting diode display device is employed as an example of the display device, but the present disclosure is not limited thereto. Any other display device may be employed as long as the technical idea of the present disclosure can be equally applied.

The shape of the electronic device 1 may be modified in a variety of ways. For example, the electronic device 1 may have shapes such as a rectangle with longer lateral sides, a rectangle with longer vertical sides, a square, a quadrangle with rounded corners (vertices), other polygons, a circle, etc. The shape of a display area DA of the electronic device 1 may also be similar to the overall shape of the electronic device 1. In the example shown in FIG. 1, the electronic device 1 has a rectangular shape with the longer sides in a second direction DR2.

The electronic device 1 may include the display area DA and a non-display area NDA. In the display area DPA, images can be displayed. In the non-display area NDA, images are not displayed. The display area DPA may be referred to as an active area, while the non-display area NDA may also be referred to as an inactive area. The display area DA may generally occupy the center of the electronic device 1.

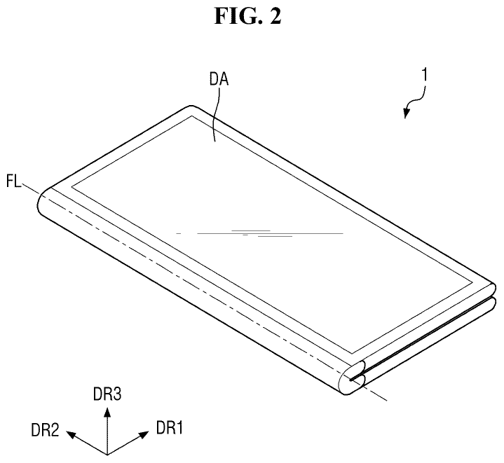

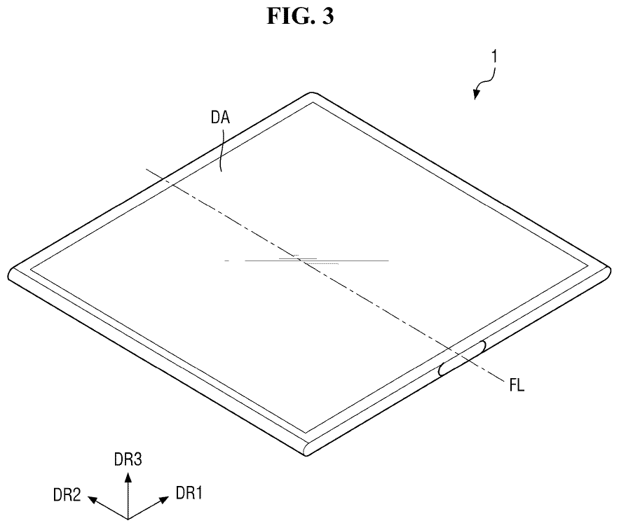

FIG. 2 is a perspective view showing a foldable display device according to an embodiment of the present disclosure when it is folded. FIG. 3 is a perspective view showing the foldable display device of FIG. 2 when it is unfolded.

Referring to FIGS. 2 and 3, an electronic device 1 according to the embodiment may be a foldable display device. The foldable display device 1 can be switched between a folded state and an unfolded state around a folding axis FL. The display area DA may be located on the outside and/or inside of the foldable electronic device 1. According to the embodiment of FIGS. 2 and 3, the display area DA is disposed on each of the outside and inside of the foldable electronic device 1.

The display area DA may be disposed on the outer side of electronic device 1. The outer surface of the electronic device 1 when it is folded may include the display area DA, and the inner surface of the electronic device 1 when it is unfolded may include the display area DA.

FIG. 4 is a perspective view showing a display device included in an electronic device according to an embodiment of the present disclosure.

Referring to FIG. 4, the electronic device 1 according to the embodiment of the present disclosure may include a display device 10. The display device 10 may provide a display screen where images are displayed in the electronic device 1. The display device 10 may have a shape similar to a shape of the electronic device 1 when viewed from the top. For example, the display device 10 may have a shape similar to a rectangle having shorter sides in the first direction DR1 and longer sides in the second direction DR2. The corners where the shorter sides in the first direction DR1 meet the longer sides in the second direction DR2 may be rounded with a predetermined curvature. It should be understood, however, that the present disclosure is not limited thereto. The corners may be formed at a right angle. The shape of the display device 10 when viewed from the top is not limited to a quadrangular shape, but may be formed in a shape similar to other polygonal shapes, a circular shape, or an elliptical shape.

The display device 10 may include a display panel 100, a display driver 200, a circuit board 300 and a touch driver 400.

The display panel 100 may include a main area MA and a subsidiary area SBA.

The main area MA may include the display area DA including pixels for displaying images, and the non-display area NDA located around the display area DA. The display area DA may output lights from a plurality of emission areas or a plurality of open areas. For example, the display panel 100 may include a pixel circuit including switching elements, a pixel-defining layer that defines the emission areas or the open areas, and self-light-emitting elements.

For example, the self-light-emitting element may include, but is not limited to, at least one of: an organic light-emitting diode including an organic light emitting layer, a quantum-dot light-emitting diode (quantum LED) including a quantum-dot light emitting layer, an inorganic light-emitting diode (inorganic LED) including an inorganic semiconductor, and a micro light-emitting diode (micro LED).

The non-display area NDA may be located on the outer side of the display area DA. The non-display area NDA may be defined as the edge of the main area MA of the display panel 100. The non-display area NDA may include a gate driver (not shown) that applies gate signals to gate lines, and fan-out lines (not shown) that connect the display driver 200 with the display area DA.

The subsidiary area SBA may be extended from one side of the main area MA. The subsidiary area SUB may include a flexible material that can be bent, folded, or rolled. For example, when the subsidiary area SBA is bent, the subsidiary area SBA may overlap the main area MA in the thickness direction (third direction DR3). The subsidiary area SBA may include pads connected to the display driver 200 and the circuit board 300. According to another embodiment, the subsidiary area SBA may be eliminated, and the display driver 200 and the pads may be disposed in the non-display area NDA.

The display driver 200 may output signals and voltages for driving the display panel 100. The display driver 200 may supply data voltages to data lines. The display driver 200 may apply a supply voltage to a voltage line and may supply gate control signals to the gate driver. The display driver 200 may be implemented as an integrated circuit (IC) and may be attached on the display panel 100 by a chip-on-glass (COG) technique, a chip-on-plastic (COP) technique, or ultrasonic bonding. For example, the display driver 200 may be disposed in the subsidiary area SBA and may overlap with the main area MA in the thickness direction as the subsidiary area SBA is bent. For another example, the display driver 200 may be mounted on the circuit board 300.

The circuit board 300 may be attached on the pad area of the display panel 100 using an anisotropic conductive film (ACF). Lead lines of the circuit board 300 may be electrically connected to the pads of the display panel 100. The circuit board 300 may be a flexible printed circuit board (FPCB), a printed circuit board (PCB), or a flexible film such as a chip-on-film (COF).

The touch driver 400 may be mounted on the circuit board 300. The touch driver 400 may be connected to a touch sensing unit of the display panel 100. The touch driver 400 may supply a touch driving signal to a plurality of touch electrodes of the touch sensing unit and may sense a change in the capacitance between the plurality of touch electrodes. For example, the touch driving signals may be pulse signals having a predetermined frequency. The touch driver 400 may determine whether there is an input and may find the coordinates of the input based on the amount of the change in the capacitance between the touch electrodes. The touch driver 400 may be implemented as an integrated circuit (IC).

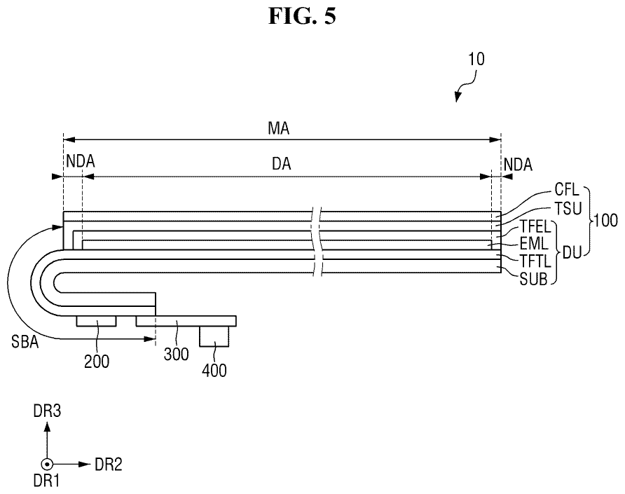

FIG. 5 is a cross-sectional view of the display device of FIG. 4 seen from the side.

Referring to FIG. 5, the display panel 100 may include a display layer DU, a touch sensing layer TSU, and a color filter layer CFL. The display layer DU may include a substrate SUB, a thin-film transistor layer TFTL, an emission material layer EML and an encapsulation layer TFEL.

The substrate SUB may be a base substrate or a base member. The substrate SUB may be a flexible substrate that can be bent, folded, or rolled. For example, the substrate SUB may include, but is not limited to, a polymer resin such as polyimide PI. According to another embodiment, the substrate SUB may include a glass material or a metal material.

The thin-film transistor layer TFTL may be disposed on the substrate SUB. The thin-film transistor layer TFTL may include a plurality of thin-film transistors forming pixel circuits of pixels. The thin-film transistor layer TFTL may include gate lines, data lines, voltage lines, gate control lines, fan-out lines for connecting the display driver 200 with the data lines, lead lines for connecting the display driver 200 with the pads, etc. Each of the thin-film transistors may include a semiconductor region, a source electrode, a drain electrode, and a gate electrode. For example, when the gate driver is formed on one side of the non-display area NDA of the display panel 100, the gate driver may include thin-film transistors.

The thin-film transistor layer TFTL may be disposed in the display area DA, the non-display area NDA and the subsidiary area SBA. The thin-film transistors in each of the pixels, the gate lines, the data lines and the voltage lines in the thin-film transistor layer TFTL may be disposed in the display area DA. The gate control lines and the fan-out lines in the thin-film transistor layer TFTL may be disposed in the non-display area NDA. The lead lines of the thin-film transistor layer TFTL may be disposed in the subsidiary area SBA.

The emission material layer EML may be disposed on the thin-film transistor layer TFTL. The emission material layer EML may include a plurality of light-emitting elements each including a pixel electrode, a common electrode and a light emitting layer to emit light, and a pixel-defining film for defining the pixels. The plurality of light-emitting elements in the emission material layer EML may be disposed in the display area DA.

According to an embodiment of the present disclosure, the light emitting layer may be an organic light emitting layer containing an organic material. The light emitting layer may include a hole transporting layer, an organic light-emitting layer and an electron transporting layer. When the pixel electrode receives a voltage and the common electrode receives a cathode voltage through the thin-film transistors in the thin-film transistor layer TFTL, the holes and electrons may move to the organic light-emitting layer through the hole transporting layer and the electron transporting layer, respectively, such that they combine in the organic light-emitting layer to emit light.

According to another embodiment, the light-emitting elements may include quantum-dot light-emitting diodes each including a quantum-dot light emitting layer, inorganic light-emitting diodes each including an inorganic semiconductor, or micro light-emitting diodes.

An encapsulation layer TFEL may cover the upper and side surfaces of the emission material layer EML, and can protect the emission material layer EML. The encapsulation layer TFEL may include at least one inorganic layer and at least one organic layer for encapsulating the emission material layer EML.

The touch sensing layer TSU may be disposed on the encapsulation layer TFEL. The touch sensing layer TSU may include a plurality of touch electrodes for sensing a user's touch by capacitive sensing, and touch lines connecting the plurality of touch electrodes with the touch driver 400. For example, the touch sensing layer TSU may sense a user's touch by mutual capacitance sensing or self-capacitance sensing.

For another example, the touch sensing layer TSU may be disposed on a separate substrate disposed on the display layer DU. In such case, the substrate supporting the touch sensing layer TSU may be a base member encapsulating the display layer DU.

The plurality of touch electrodes of the touch sensing layer TSU may be disposed in a touch sensor area overlapping the display area DA. The touch lines of the touch sensing layer TSU may be disposed in a touch peripheral area overlapping the non-display area NDA.

The color filter layer CFL may be disposed on the touch sensing layer TSU. The color filter layer CFL may include a plurality of color filters associated with the plurality of emission areas, respectively. Each of the color filters may selectively transmit light of a particular wavelength and block or absorb lights of other wavelengths. The color filter layer CFL may absorb some of lights introduced from the outside of the display device 10 to reduce the reflection of external light. Accordingly, the color filter layer CFL can prevent distortion of colors due to the reflection of external light. The polarization member POL may function as an anti-reflection layer.

Since the color filter layer CFL is disposed directly on the touch sensing layer TSU, the display device 10 may require no separate substrate for the color filter layer CFL. Therefore, the thickness of the display device 10 can be relatively small.

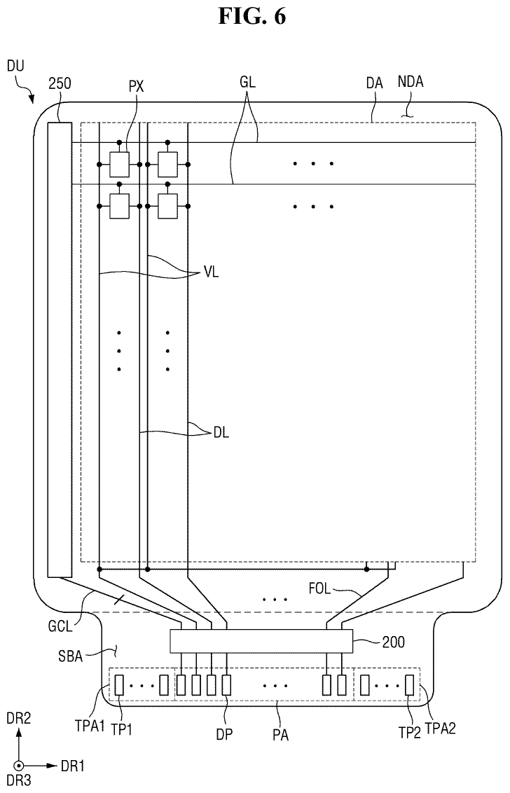

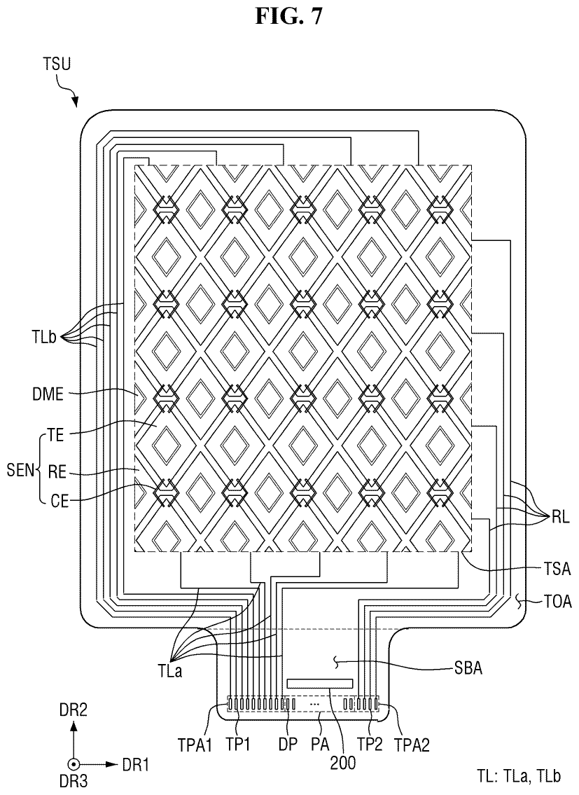

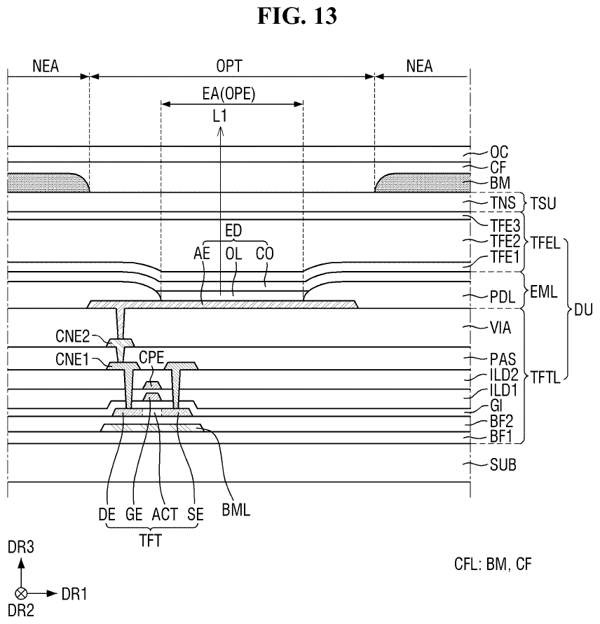

FIG. 6 is a plan view showing a display layer of a display device according to an embodiment of the present disclosure. As used herein, the “plan view” is a view in a thickness direction (i.e., the third direction DR3) of the substrate SUB (See FIG. 13).

Referring to FIG. 6, the display layer DU may include a display area DA and a non-display area NDA.

The display area DA may be disposed at the center of display device 10. In the display area DA, a plurality of pixels PX, a plurality of gate lines GL, a plurality of data lines DL and a plurality of voltage lines may be disposed. Each of the plurality of pixels PX may be defined as the minimum unit that outputs light.

The plurality of gate lines GL may supply the gate signals received from the gate driver 250 to the plurality of pixels PX. The plurality of gate lines GL may be extended in the first direction DR1 and may be spaced apart from one another in the second direction DR2 intersecting the first direction DR1.

The plurality of data lines DL may supply the data voltages received from the display driver 200 to the plurality of pixels PX. The plurality of data lines DL may be extended in the second direction DR2 and may be spaced apart from one another in the first direction DR1.

The plurality of voltage lines VL may apply the supply voltage received from the display driver 200 to the plurality of pixels PX. The supply voltage may be at least one of a driving voltage, an initialization voltage, a reference voltage and a low-level voltage. The plurality of voltage lines VL may be extended in the second direction DR2 and may be spaced apart from one another in the first direction DR1.

The non-display area NDA may surround the display area DA. In the non-display area NDA, the gate driver 250, fan-out lines FOL, and gate control lines GCL may be disposed. The gate driver 250 may generate a plurality of gate signals based on the gate control signal and may sequentially supply the plurality of gate signals to the plurality of gate lines GL in a predetermined order.

The fan-out lines FOL may be extended from the display driver 200 to the display area DA. The fan-out lines FOL may supply the data voltage received from the display driver 200 to the plurality of data lines DL.

A gate control line GCL may be extended from the display driver 200 to the gate driver 250. The gate control line GCL may supply the gate control signal received from the display driver 200 to the gate driver 250.

The subsidiary area SBA may include the display driver 200, a pad area DPA, and first and second touch pad areas TPA1 and TPA2.

The display driver 200 may output signals and voltages for driving the display panel 100 to the fan-out lines FOL. The display driver 200 may supply data voltages to the data lines DL through the fan-out lines FOL. The data voltages may be applied to the plurality of pixels PX, so that the brightness of the plurality of pixels PX may be controlled. The display driver 200 may supply a gate control signal to the gate driver 250 through the gate control lines GCL.

The pad area DPA, the first touch pad area TPA1 and the second touch pad area TPA2 may be disposed at the edge of the subsidiary area SBA. The pad area PA, the first touch pad area TPA1 and the second touch pad area TPA2 may be electrically connected to the circuit board 300 using a material such as an anisotropic conductive film and a self assembly anisotropic conductive paste (SAP). The first touch pad area TPA1 may include first touch pads TP1, the second touch pad area TPA2 may include second touch pads TP2, and they may be electrically connected to the circuit board 300.

The pad area PA may include a plurality of display pads DP. The plurality of display pads DP may be connected to a graphic system through the circuit board 300. The plurality of display pads DP may be connected to the circuit board 300 to receive digital video data and may supply the digital video data to the display driver 200.

FIG. 7 is a plan view showing a touch sensing layer of a display device according to an embodiment of the present disclosure.

Referring to FIG. 7, the touch sensing layer TSU may include a touch sensor area TSA that senses a user's touch, and a touch peripheral area TOA disposed around the touch sensor area TSA. The touch sensor area TSA may be disposed in the display area DA of the display device 10, and the touch peripheral area TOA may be disposed in the non-display area NDA of the display device 10.

The touch sensor area TSA may include a plurality of touch electrodes SEN and a plurality of dummy electrodes DME. The plurality of touch electrodes SEN may form mutual capacitance or self capacitance to sense a touch of an object or person. The plurality of touch electrodes SEN may include a plurality of driving electrodes TE, a plurality of sensing electrodes RE, and bridge electrodes CE.

The driving electrodes TE may be arranged in the first direction DR1 and in the second direction DR2. The driving electrodes TE may be spaced apart from one another in the first direction DR1 and in the second direction DR2. The driving electrodes TE adjacent to one another in the second direction DR2 may be electrically connected through bridge electrodes CE.

The plurality of driving electrodes TE may be connected to the first touch pads TP1 through driving lines TL. The driving lines TL may include lower driving lines TLa and upper driving lines TLb. For example, the driving electrodes TE disposed on the lower side of the touch sensor area TSA may be connected to the first touch pads TP1 through the lower driving lines TLa, and the driving electrodes TE disposed on the upper side of the touch sensor area TSA may be connected to the first touch pads TP1 through the upper driving lines TLb. The lower driving lines TLa may be extended to the first touch pads TP1 beyond the lower side of the touch peripheral area TOA. The upper driving lines TLb may be extended to the first touch pads TP1 via the upper side, the left side and the lower side of the touch peripheral area TOA. The first touch pads TP1 may be connected to the touch driver 400 through the circuit board 300.

The bridge electrodes CE may be bent at least once. Although the bridge electrodes CE may have the shape of angle brackets “<” or “>”, the shape of the bridge electrodes CE when viewed from the top is not limited thereto. The driving electrodes TE adjacent to one another in the second direction DR2 may be connected by the plurality of bridge electrodes CE. Even if one of the bridge electrodes CE is disconnected, the driving electrodes TE can be stably connected through the remaining bridge electrodes CE. The driving electrodes TE adjacent to each other may be connected by two bridge electrodes CE, but the number of bridge electrodes CE is not limited thereto.

The bridge electrodes CE may be disposed on a different layer from the plurality of driving electrodes TE and the plurality of sensing electrodes RE. The sensing electrodes RE adjacent to one another in the first direction DR1 may be electrically connected through connectors disposed in the same layer as the plurality of driving electrodes TE or the plurality of sensing electrodes RE. The driving electrodes TE adjacent to one another in the second direction DR2 may be electrically connected through the bridge electrodes CE disposed in a different layer from the plurality of driving electrodes TE or the plurality of sensing electrodes RE. Accordingly, even though the bridge electrodes CE overlap with the plurality of sensing electrodes RE in the z-axis direction, the plurality of driving electrodes TE and the plurality of sensing electrodes RE can be insulated from each other. Mutual capacitance may be formed between the driving electrodes TE and the sensing electrodes RE.

The sensing electrodes TE may be extended in the first direction DR1 and may be spaced apart from one another in the second direction DR2. The sensing electrodes RE may be arranged in the first direction DR1 and the second direction DR2, and the sensing electrodes RE adjacent to one another in the first direction DR1 may be electrically connected through connectors.

The plurality of sensing electrodes RE may be connected to second touch pads TP2 through sensing lines RL. For example, the sensing electrodes RE disposed on the right side of the touch sensor area TSA may be connected to the second touch pads TP2 through the sensing lines RL. The sensing lines RL may be extended to the second touch pads TP2 along the right side and the lower side of the touch peripheral area TOA. The second touch pads TP2 may be connected to the touch driver 400 through the circuit board 300.

Each of the plurality of dummy electrodes DME may be surrounded by the driving electrode TE or the sensing electrode RE. Each of the plurality of dummy electrodes DME may be spaced apart from and insulated from the driving electrode TE or the sensing electrode RE. Accordingly, the dummy electrodes DME may be electrically floating.

The pad area DPA, the first touch pad area TPA1 and the second touch pad area TPA2 may be disposed at the edge of the subsidiary area SBA. The pad area PA, the first touch pad area TPA1 and the second touch pad area TPA2 may be electrically connected to the circuit board 300 using a low-resistance, high-reliability material such as an anisotropic conductive film and a self assembly anisotropic conductive paste (SAP).

The first touch pad area TPA1 may be disposed on one side of the pad area PA and may include a plurality of first touch pads TP1. The plurality of first touch pads TP1 may be electrically connected to the touch driver 400 disposed on the circuit board 300. The plurality of first touch pads TP1 may supply touch driving signals to the plurality of driving electrodes TE through the plurality of driving lines TL.

The second touch pad area TPA2 may be disposed on the opposite side of the pad area PA and may include a plurality of second touch pads TP2. The plurality of second touch pads TP2 may be electrically connected to the touch driver 400 disposed on the circuit board 300. The touch driver 400 may receive a touch sensing signal through the plurality of sensing lines RL connected to the plurality of second touch pads TP2, and may sense a change in the capacitance between the driving electrodes TE and the sensing electrodes RE.

According to another embodiment, the touch driver 400 may supply a touch driving signal to each of the plurality of driving electrodes TE and the plurality of sensing electrodes RE, and may receive a touch sensing signal from each of the plurality of driving electrodes TE and the plurality of sensing electrodes RE. The touch driver 400 may sense a change in the amount of charges in each of the plurality of driving electrodes TE and the plurality of sensing electrodes RE based on the touch sensing signal.

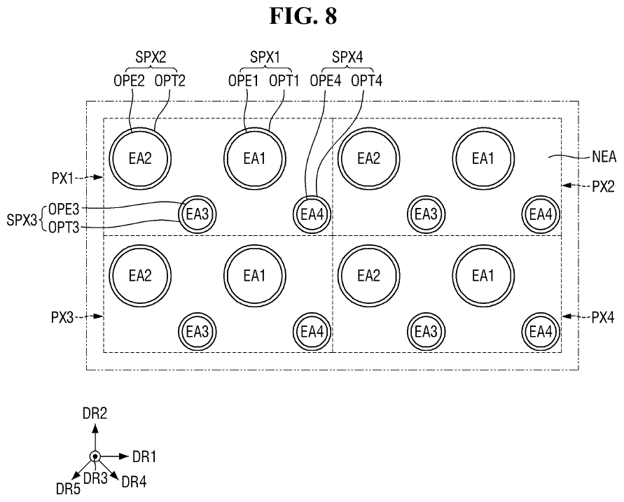

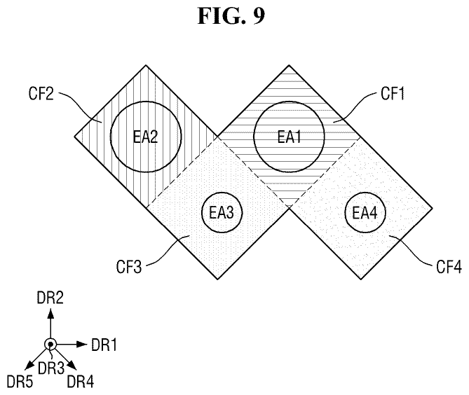

FIG. 8 is a plan view showing arrangements of emission areas in a display area of a display device according to an embodiment. FIG. 9 is a plan view showing a layout of color filters arranged in the display area of FIG. 8.

Referring to FIGS. 8 and 9, the display device 10 may include a plurality of pixel groups PX1, PX2, PX3 and PX4 arranged in the display area DA, and a plurality of emission areas EA1, EA2, EA3 and EA4 and a non-emission area NEA located in each of the pixel groups PX1, PX2, PX3 and PX4. The plurality of pixel groups PX1, PX2, PX3 and PX4 may be arranged in the first direction DR1 and the second direction DR2. The first pixel group PX1 and the second pixel group PX2 may be arranged alternately in the first direction DR1, and the third pixel group PX3 and the fourth pixel group PX4 may be arranged alternately in the first direction DR1. The first pixel group PX1 and the third pixel group PX3 may be arranged alternately in the second direction DR2, and the second pixel group PX2 and the fourth pixel group PX4 may be arranged alternately in the second direction DR2.

The pixel groups PX1, PX2, PX3 and PX4 may be arranged in a PenTile™ matrix, for example, a diamond PenTile™ matrix in the display area DA. It should be understood, however, that the layout or arrangement of the pixel groups PX1, PX2, PX3 and PX4 is not limited to that shown in FIGS. 8 and 9. In some embodiments, the plurality of pixel groups PX1, PX2, PX3 and PX4 may be arranged in a linear pattern or an island-like pattern.

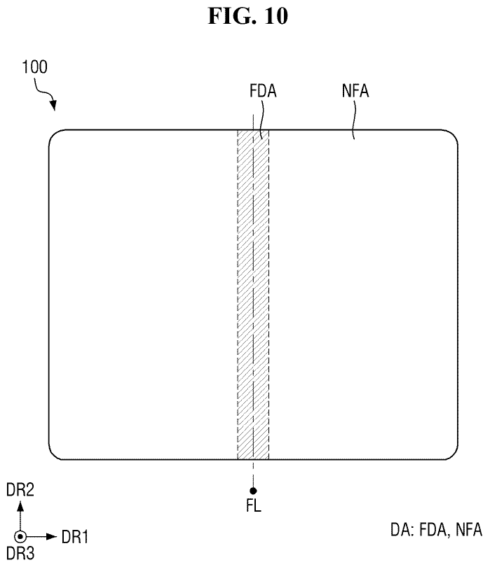

The emission areas EA1, EA2, EA3 and EA4 of each of the pixel groups PX1, PX2, PX3 and PX4 may include a first emission area EA1, a second emission area EA2, a third emission area EA3 and a fourth emission area EA4 that emit lights of different colors. Unlike the first emission area EA1 and the second emission area EA2, the third emission area EA3 and the fourth emission area EA4 may emit lights of the same color. Each of the first to fourth emission areas EA1, EA2, EA3 and EA4 may emit red, blue or green light. The colors of lights emitted from the emission areas EA1, EA2, EA3 and EA4 may vary depending on the type of light-emitting elements ED (see FIG. 10) disposed in the emission material layer EML to be described later. According to an embodiment, the first emission area EA1 may emit first light of red color, the second emission area EA2 may emit second light of blue color, and the third emission area EA3 and the fourth emission area EA4 may emit third light of green color. It is, however, to be understood that the present disclosure is not limited thereto.

The emission areas EA1, EA2 EA3 and EA4 may be arranged in a PenTile™ matrix, for example, a diamond PenTile™ matrix. For example, in each of the pixel groups PX1, PX2, PX3 and PX4, the first emission area EA1 and the second emission area EA2 may be arranged such that they are spaced apart from each other in the first direction DR1, and the third emission area EA3 and the fourth emission area EA4 may be arranged such that they are spaced apart from each other in the first direction DR1. The first emission area EA1 may be spaced apart from the third emission area EA3 in a fifth direction DR5, and may be spaced apart from the fourth emission area EA4 in a fourth direction DR4. The second emission area EA2 may be spaced apart from the third emission area EA3 in the fourth direction DR4.

The emission areas EA1, EA2, EA3 and EA4 may be arranged in the first direction DR1 or the second direction DR2. The first emission area EA1 and the second emission area EA2 may be arranged alternately in the first direction DR1. The third emission area EA3 and the fourth emission area EA4 may be arranged alternately in the first direction DR1.

The first to fourth emission areas EA1, EA2, EA3 and EA4 may be defined by a plurality of openings OPE1, OPE2, OPE3 and OPE4 formed in a pixel-defining layer PDL (see FIG. 10) of the emission material layer EML, which will be described later. For example, the first emission area EA1 may be defined by the first opening OPEL of the pixel-defining layer, the second emission area EA2 may be defined by the second opening OPE2 of the pixel-defining layer, the third emission area EA3 may be defined by the third opening OPE3 of the pixel-defining layer, and the fourth emission area EA4 may be defined by the fourth opening OPE4 of the pixel-defining layer.

According to an embodiment of the present disclosure, some of the first to fourth emission areas EA1, EA2, EA3 and EA4 may have the same area or size while some others of them may have different areas or sizes. According to the embodiment of FIG. 8, the size of the first emission area EA1 may be equal to the size of the second emission area EA2 and may be greater than the sizes of the third emission area EA3 and the fourth emission area EA4. The third emission area EA3 and the fourth emission area EA4 may have the same size. The sizes of the emission areas EA1, EA2, EA3 and EA4 may vary depending on the sizes of the opening OPE1, OPE2, OP3 and OPE4 formed in the pixel-defining layer. The intensity of lights emitted from the emission areas EA1, EA2, EA3 and EA4 may vary depending on the size of the emission areas EA1, EA2, EA3 and EA4. The colors of the images displayed on the display device 10 or the electronic device 1 can be controlled by adjusting the size of the emission areas EA1, EA2, EA3 and EA4. Although the first emission area EA1 and the second emission area EA2 have the same size according to the embodiment of FIG. 8, the present disclosure is not limited thereto. In some embodiments, the first emission area EA1 may be larger than the second emission area EA2. The size of the emission areas EA1, EA2, EA3 and EA4 may be adjusted as desired according to the colors of the images required by the display device 10 and the electronic device 1. In addition, the sizes of the emission areas EA1, EA2, EA3 and EA4 may be related to light efficiency, lifespan of the light-emitting elements ED, etc., and may have a trade-off relationship with reflection of external light. The sizes of the emission areas EA1, EA2, EA3 and EA4 may be adjusted by taking the above factors into account.

In addition, the plurality of openings OPE1, OPE2, OPE3 and OPE4 and the plurality of light output areas OPT1, OPT2, OPT3 and OPT4 have a circular shape in the example shown in the drawings, the present disclosure is not limited thereto. They may have a variety of shapes, such as an oval shape and a polygonal shape with rounded edges.

Each of the plurality of pixel groups PX1, PX2, PX3 and PX4 may include first to fourth emission areas EA1, EA2, EA3 and EA4 arranged adjacent to each other, and may represent black-and-white or grayscale images. It should be understood, however, that the present disclosure is not limited thereto. The combination of the emission areas EA1, EA2, EA3 and EA4 forming a single pixel group may be modified depending on the arrangement of the emission areas EA1, EA2, EA3 and EA4, and the colors of the lights emitted from them.

The non-emission area NEA may be the other area than the emission areas EA1, EA2, EA3 and EA4. The non-emissive area NEA may be located between the emission areas EA1, EA2, EA3 and EA4. The non-emission area NEA may overlap with the pixel-defining layer. For example, the non-emission area NEA may be identical to the area of the pixel-defining layer.

The display device 10 may include a plurality of color filters CF1, CF2, CF3 and CF4 disposed on the emission areas EA1, EA2, EA3 and EA4. The color filters CF1, CF2, CF3 and CF4 may be associated with the emission areas EA1, EA2, EA3 and EA4, respectively. For example, the color filters CF1, CF2, CF3 and CF4 may be disposed in line with the emission areas EA1, EA2, EA3 and EA4, or the openings OPE1, OPE2, OPE3 and OPE4 or a plurality of light output areas OPT1, OPT2, OPT3 and OPT4. A plurality of light output areas OPT1, OPT2, OPT3 and OPT4 may be defined by a light-blocking pattern BM (see FIG. 13), may be disposed to overlap with the openings OPE1, OPE2, OPE3 and OPE4 in a plan view, and may form light exit areas where lights emitted from the emission areas EA1, EA2, EA3 and EA4 exit. The color filters CF1, CF2, CF3 and CF4 may have a larger area than the light output areas OPT1, OPT2, OPT3 and OPT4, and the openings OPE1, OPE2, OPE3 and OPE4. The color filters CF1, CF2, CF3 and CF4 may completely cover the light exit areas formed by the light output areas OPT1, OPT2, OPT3 and OPT4.

The color filters CF1, CF2, CF3 and CF4 may be disposed in different emission areas EA1, EA2, EA3 and EA4, respectively. The color filters CF1, CF2, CF3 and CF4 may include the first color filter CF1, the second color filter CF2 the third color filter CF3 and the fourth color filter CF4. The color filters CF1, CF2, CF3 and CF4 may include a colorant such as a dye and pigment that absorbs lights in wavelength ranges other than light in a particular wavelength range, and may be disposed in association with the lights exiting from the emission areas EA1, EA2, EA3 and EA4.

For example, the first color filter CF1 may be a red color filter that is disposed to overlap with the first emission area EA1 and transmits only red first light. The second color filter CF2 may be a blue color filter that is disposed to overlap with the second emission area EA2 and transmits only blue second light. The third color filter CF3 may be disposed to overlap with the third emission area EA3, and the fourth color filter CF4 may be disposed to overlap with the fourth emission area EA4. The third color filter CF3 and the fourth color filter CF4 may be green color filters that transmit only graph third light.

The first color filter CF1 may be in line with the first emission area EA1 but not with the second emission area EA2, the third emission area EA3 or the fourth emission area EA4. The second color filter CF2 may be in line with the second emission area EA2 but not with the first emission area EA1, the third emission area EA3 or the fourth emission area EA4. The third color filter CF3 may be in line with the third emission area EA3 but not with the first emission area EA1, the second emission area EA2 or the fourth emission area EA4. The fourth color filter CF4 may be in line with the fourth emission area EA4 but not with the first emission area EA1, the second emission area EA2 or the third emission area EA3.

In the display device 10, the colors of reflected lights by external light can be controlled by adjusting the arrangement, shape and area of the color filters CF1, CF2, CF3 and CF4 when viewed from the top.

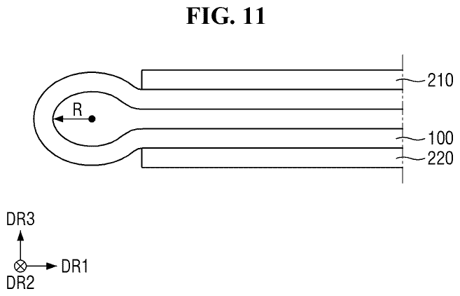

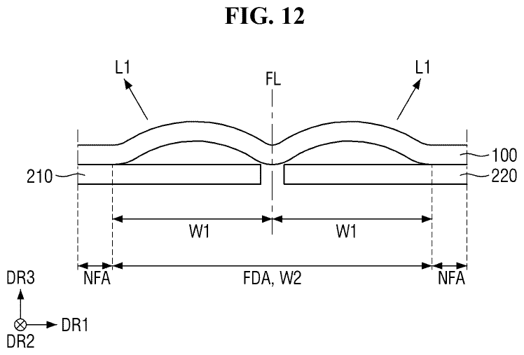

FIG. 10 is a plan view schematically showing a display panel of a display device according to an embodiment of the present disclosure. FIG. 11 is a cross-sectional view schematically showing the display panel of the display device according to the embodiment of the present disclosure when it is folded. FIG. 12 is a cross-sectional view schematically showing the folding area of the display device of FIG. 10.

Referring to FIGS. 10 to 12, the display panel 100 according to the embodiment may be folded over the folding axis FL. For example, the folding axis FL may be extended in the second direction DR2, and the display panel 100 may be folded in the first direction DR1 over the folding axis FL.

The display panel 100 may include a display area DA, and the display area DA may include a folding area FDA including the folding axis FL, and a non-folding area NFA other than the folding area FDA. For example, the folding area FDA may be extended along the folding axis FL in the second direction DR2 at the center of the display panel 100, and the non-folding area NFA may be disposed on the opposite sides of the folding area FDA. The folding area FDA and the non-folding area NFA may be defined on a substrate SUB (see FIG. 13) of the display panel 100. The folding area FDA may have a width W1 of 0.75πR to 1.25πR from each side of the folding axis FL to the folding axis FL in a direction perpendicular to the folding axis FL (a first side and a second side in the first direction DR1). Accordingly, the total width W2 of the folding area FDA (See FIG. 12) may range from 1.5πR to 2.5πR. Here, R is a radius of curvature at the folding area FDA in a folded state.

When the display panel 100 is folded, the folding area FDA may have a curved surface. For example, the folding area FDA may be a curved portion that is bent when the display panel 100 is folded, and the non-folding area NFA may be a flat portion that is extended from the curved portion and is flat even when that display panel 100 is folded. When the display panel 100 is folded, the display panel 100 may have the radius of curvature R at the folding area FDA. That is to say, the display panel 100 may be folded with the radius of curvature R. For example, the radius of curvature R may be measured as the radius of an arc formed by the folding area FDA of the display panel 100 when the display panel 100 is folded. According to an embodiment of the present disclosure, the longest radius among the radii of the arc formed by the folding area FDA of the display panel 100 may be referred to as the radius of curvature R. According to another embodiment of the present disclosure, the shortest radius among the radii of the arc formed by the folding area FDA of the display panel 100 may be referred to as the radius of curvature R.

The display device 10 may include a first plate 210 and a second plate 220 disposed under the display panel 100. The first plate 210 and the second plate 220 may be separated from each other and may be coupled to each other by a hinge. The first plate 210 may be placed on one side of the folding area FDA, and the second plate 220 may be placed on the opposite side of the folding area FDA. When the display panel 100 is folded, the first plate 210 may be located on the upper side of the display panel 100, and the second plate 220 may be located on the lower side of the display panel 100.

When the display panel 100 is unfolded, the display panel 100 may have a curved surface in the folding area FDA. For example, the display panel 100 may be spaced apart from the first plate 210 and the second plate 220 in the folding area FDA in the third direction DR3, such that parts of the display panel 100 may have a convex shape in the third direction DR3. That is to say, as the display panel 100 has the curved surface in the folding area FDA, it is possible to create a margin so that the display panel 100 can be easily folded with a predetermined radius of curvature R.

Referring to FIG. 12, when the display panel 100 is unfolded, light L1 may exit to sides rather than the front (i.e., the third direction DR3) due to the curved surface of the display panel 100 on the outer sides in the folding area FDA, which may lower brightness at the front. As a result, there may be a difference in brightness between the folding area FDA and the non-folding area NFA of the display panel 100 in the unfolded state, thereby deteriorating display quality.

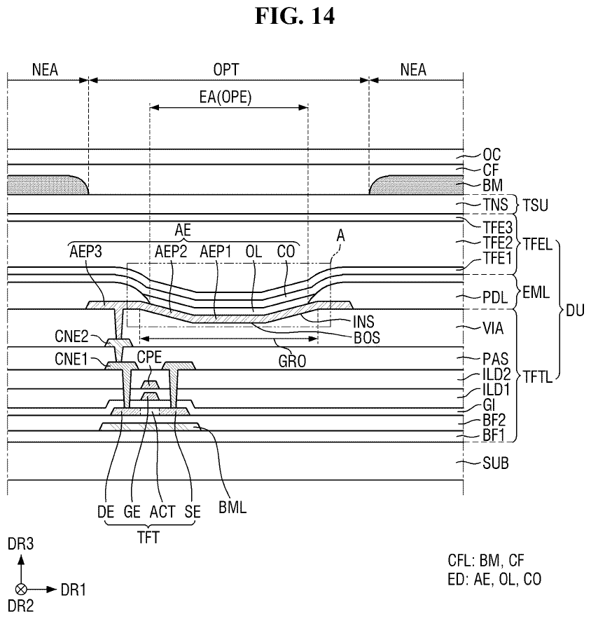

According to this embodiment of the present disclosure, the structure of the display layer DU (see FIG. 13) is different between the folding area FDA and the non-folding area NFA of the display panel 100 of the display device 10 (See FIGS. 13 and 14), so that the brightness difference between the folding area FDA and the non-folding area NFA can be reduced.

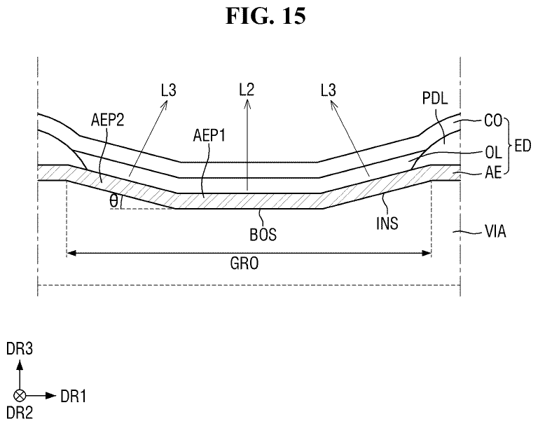

FIG. 13 is a cross-sectional view showing a pixel in a non-folding area of a display device according to an embodiment of the present disclosure. FIG. 14 is a cross-sectional view showing a pixel in a folding area of a display device according to an embodiment of the present disclosure. FIG. 15 is an enlarged view of area A of FIG. 14.

The cross-sectional structure of a plurality of pixels SPXn disposed in the non-folding area NFA of the display panel 100 will be described with reference to FIG. 13.

Referring to FIG. 13, the display panel 100 of the display device 10 according to an embodiment may include a display layer DU, a touch sensing layer TSU, a color filter layer CFL and an overcoat layer OC. The display layer DU may include a substrate SUB, a thin-film transistor layer TFTL, an emission material layer EML and an encapsulation layer TFEL.

The substrate SUB may be a base substrate or a base member. The substrate SUB may be a flexible substrate that can be bent, folded, or rolled. For example, the substrate SUB may include, but is not limited to, a polymer resin such as polyimide PI. For another example, the substrate SUB may include a glass material or a metal material.

The thin-film transistor layer TFTL may include a first buffer layer BF1, a bottom metal layer BML, a second buffer layer BF2, a thin-film transistor TFT, a gate insulator GI, a first interlayer-dielectric layer ILD1, a capacitor electrode CPE, a second interlayer-dielectric layer ILD2, a first connection electrode CNE1, a passivation layer PAS, a second connection electrode CNE2 and a via-layer VIA.

The first buffer layer BF1 may be disposed on the substrate SUB. The first buffer layer BF1 may include an inorganic film capable of preventing permeation of air or moisture. For example, the first buffer layer BF1 may include a plurality of inorganic films stacked on one another alternately.

The bottom metal layer BML may be disposed on the first buffer layer BF1. For example, the bottom metal layer BML may be made up of a single layer or multiple layers of one of molybdenum (Mo), aluminum (Al), chromium (Cr), gold (Au), titanium (Ti), nickel (Ni), neodymium (Nd), Tantalum (Ta) and copper (Cu) or an alloy thereof.

The second buffer layer BF2 may cover the first buffer layer BF1 and the bottom metal layer BML. The second buffer layer BF2 may include an inorganic film capable of preventing permeation of air or moisture. For example, the second buffer layer BF2 may include a plurality of inorganic films stacked on one another alternately.

The thin-film transistor TFT may be disposed on the second buffer layer BF2 and may form a pixel circuit of each of a plurality of pixels. For example, the thin-film transistor TFT may be a driving transistor or a switching transistor of the pixel circuit. The thin-film transistor TFT may include a semiconductor layer ACT, a source electrode SE, a drain electrode DE and a gate electrode GE.

The semiconductor layer ACT may be disposed on the second buffer layer BF2. The semiconductor layer ACT may overlap the bottom metal layer BML and the gate electrode GE in the thickness direction (i.e., the third direction DR3) and may be insulated from the gate electrode GE by the gate insulator GI. The material of a portion of the semiconductor layer ACT may be made conductive to form the source electrode SE and the drain electrode DE.

The gate electrode GE may be disposed on the gate insulator GI. The gate electrode GE may overlap the semiconductor layer ACT with the gate insulating layer GI interposed therebetween.

The gate insulator GI may be disposed on the semiconductor layer ACT. For example, the gate insulator GI may cover the semiconductor layer ACT and the second buffer layer BF2 and may insulate the semiconductor layer ACT from the gate electrode GE. The gate insulator GI may include a contact hole through which the first connection electrode CNE1 passes.

The first interlayer-dielectric layer ILD1 may cover the gate electrode GE and the gate insulator GI. The first interlayer-dielectric layer ILD1 may include a contact hole through which the first connection electrode CNE1 passes. The contact holes of the first interlayer-dielectric layer ILD1 may be connected to the contact holes of the gate insulator GI and the contact holes of the second interlayer-dielectric layer ILD2.

The capacitor electrode CPE may be disposed on the first interlayer-dielectric layer ILD1. The capacitor electrode CPE may overlap with the gate electrode GE in the thickness direction (i.e., the third direction DR3). The capacitor electrode CPE and the gate electrode GE may form a capacitance.

The second interlayer-dielectric layer ILD2 may cover the capacitor electrode CPE and the first interlayer-dielectric layer ILD1. The second interlayer-dielectric layer ILD2 may include a contact hole through which the first connection electrode CNE1 passes. The contact hole of the second interlayer-dielectric layer ILD2 may be connected to the contact hole of the first interlayer-dielectric layer ILD1 and the contact hole of the gate insulator GI.

The first connection electrode CNE1 may be disposed on the second interlayer-dielectric layer ILD2. The first connection electrode CNE1 may electrically connect the drain electrode DE of the thin-film transistor TFT with the second connection electrode CNE2. The first connection electrode CNE1 may be inserted into a contact hole formed in the second interlayer-dielectric layer ILD2, the first interlayer-dielectric layer ILD1, and the gate insulator GI to be in contact with the drain electrode DE of the thin-film transistor TFT.

The passivation layer PAS may cover the first connection electrode CNE1 and the second interlayer-dielectric layer ILD2. The passivation layer PAS can protect the thin-film transistor TFT. The passivation layer PAS may include a contact hole through which the second connection electrode CNE2 passes.

The second connection electrode CNE2 may be disposed on the passivation layer PAS. The second connection electrode CNE2 may electrically connect the first connection electrode CNE1 with a pixel electrode AE of the light-emitting element ED. The second connection electrode CNE2 may be inserted into the contact hole formed in the passivation layer PAS to be in contact with the first connection electrode CNE1.

The via-layer VIA may cover the second connection electrode CNE2 and a first passivation layer PAS1. The via-layer VIA may define a contact hole through which the pixel electrode AE of the light-emitting diode ED passes. The via-layer VIA may be formed of or include an organic material, e.g., an acryl resin, an epoxy resin, a phenolic resin, a polyamide resin, a polyimide resin, etc. The via-layer VIA may be an insulating layer.

The emission material layer EML may be disposed on the thin-film transistor layer TFTL. The emission material layer EML may include a light-emitting element ED and a pixel-defining layer PDL. The light-emitting diode ED may include the anode electrode AE, a light emitting layer EL, and a common electrode CO.

The pixel electrode AE may be disposed on the via-layer VIA. The pixel electrode AE may be disposed in line with an opening OPE of a pixel-defining layer PDL. The pixel electrode AE may be electrically connected to the drain electrode DE of the thin-film transistor TFT through the first and second connection electrodes CNE1 and CNE2.

The light emitting layer EL may be disposed on the pixel electrode AE. The light emitting layer EL may be disposed in the opening OPE of the pixel-defining layer PDL. For example, the light emitting layer EL may be, but is not limited to, an organic light emitting layer made of an organic material. If the light emitting layer EL is an organic light emitting layer, when the thin-film transistor applies a predetermined voltage to the pixel electrode AE of the light-emitting diode ED and the common electrode CO of the light-emitting diode ED receives a common voltage or cathode voltage, the holes and electrons may move to the light emitting layer EL through the hole transporting layer and the electron transporting layer, respectively, and they combine in the light emitting layer EL to emit light.

The common electrode CO may be disposed on the light emitting layer EL. The common electrode CO may be an opposing electrode (e.g., counter electrode) facing the pixel electrodes AE. For example, the common electrode CO may be implemented as an electrode common to all pixels, instead of being disposed as a separated electrode for each of the pixels. The common electrode CO may be disposed on the light emitting layer EL in the first to third emission areas EA1, EA2 and EA3, and may be disposed on the pixel-defining layer PDL in the other areas than the first to third emission areas EA1, EA2 and EA3.

The common electrode CO may receive a common voltage or a low-level voltage. When the pixel electrode AE receives the voltage equal to the data voltage and the common electrode CO receives the low-level voltage, a potential difference is formed between the pixel electrode AE and the common electrode CO, so that the light emitting layer EL can emit light.

The pixel-defining layer PDL defining the opening OPE therein may be disposed on the via-layer VIA and a portion of the pixel electrode AE. The pixel-defining layer PDL may define the opening OPE therein, and the opening OPE may expose a portion of the pixel electrode AE. For example, the pixel-defining layer PDL may cover an edge of the pixel electrode AE, exposing a portion of the pixel electrode AE. As described above, the opening OPE of the pixel-defining layer PDL may define an emission area EA. The pixel-defining layer PDL may separate and insulate the pixel electrode AE of the light-emitting element ED from the pixel electrode of another one.

The pixel-defining layer PDL may include a light-absorbing material to prevent light reflection. For example, the pixel-defining layer PDL may include a polyimide (PI)-based binder, and pigments in which red, green and blue are mixed. Alternatively, the pixel-defining layer PDL may include a cardo-based binder resin and a mixture of lactam black pigment and blue pigment. Alternatively, the pixel-defining layer PDL may include carbon black.

The encapsulation layer TFEL may be disposed on the common electrode CO to cover the light-emitting diodes ED. The encapsulation layer TFEL may include at least one inorganic layer to prevent permeation of oxygen or moisture into the emission material layer EML. The encapsulation layer TFEL may include at least one organic layer to protect the emission material layer EML from foreign substances such as dust.

The encapsulation layer TFEL may include a first encapsulation layer TFE1, a second encapsulation layer TFE2 and a third encapsulation layer TFE3. The first encapsulation layer TFE1 and the third encapsulation layer TFE3 may be inorganic encapsulation layers, and the second encapsulation layer TFE2 disposed therebetween may be an organic encapsulation layer.

Each of the first encapsulation layer TFE1 and the third encapsulation layer TFE3 may include one or more inorganic insulating materials. The inorganic insulating material may include aluminum oxide, titanium oxide, tantalum oxide, hafnium oxide, zinc oxide, silicon oxide, silicon nitride, and/or silicon oxynitride.

The second encapsulation layer TFE2 may include an organic insulating material. Organic insulating materials may include, for example, an acrylic resin, an epoxy resin, polyimide, polyethylene, etc. The second encapsulation layer TFE2 may be formed by curing a monomer or by applying a polymer.

The touch sensing layer TSU may be disposed on the encapsulation layer TFEL. The touch sensing layer TSU may include a touch insulating layer TNS. Although not shown in the drawings, the touch sensing layer TSU may include the driving electrodes, the sensing electrodes and the bridge electrodes shown in FIG. 7.

The touch insulating layer TNS may be disposed on the third encapsulation layer TFE3. The touch insulating layer TNS may include an organic film or an inorganic film. For example, the touch insulating layer TNS may include an organic film such as an acrylic resin, an epoxy resin, polyimide and polyethylene, or may include an inorganic film such as silicon nitride, silicon oxide and silicon nitride.

The color filter layer CFL may be disposed on the touch sensing layer TSU. The color filter layer CFL may include a color filter CF and a light-blocking pattern BM. The color filter may selectively transmit light of a particular wavelength and block or absorb lights of other wavelengths. The color filter layer CFL may absorb some of lights introduced from the outside of the display device 10 to reduce the reflection of external light. Accordingly, the color filter layer CFL can prevent distortion of colors due to the reflection of external light.

The light-blocking pattern BM may be disposed on the touch insulating layer TNS of the touch sensing layer TSU. The light-blocking pattern BM may define the light output area OPT in line with the emission area EA. The area or size of the light output area OPT may be larger than the area or size of the opening OPE of the pixel-defining layer PDL in a plan view. As the light output area OPT of the light-blocking layer BM is larger than the opening OPE of the pixel-defining layer PDL, the lights output from the emission area EA may be seen by a user not only from the front but also from the sides of the display device 10.

The light-blocking pattern BM may include a light-absorbing material. For example, the light-blocking pattern BM may include an inorganic black pigment or an organic black pigment. The inorganic black pigment may be, but is not limited to, carbon black, and the organic black pigment may include, but is not limited to, at least one of lactam black, perylene black, and aniline black. The light-blocking pattern BM can prevent visible light from penetrating and mixing colors between the emission areas EA to improve the color gamut of the display device 10.

The color filter CF of the color filter layer CFL may be disposed on the light-blocking pattern BM and the touch insulating layer TNS. The color filter CF may overlap the light output area OPT and the emission area EA, and a portion of the color filter CF may overlap the non-emission area NEA. The color filter CF may block or absorb one of the light of the first color (e.g., red light), the light of the second color (e.g., blue light) and the light of the third color (e.g., green light).

The overcoat layer OC may be disposed on the color filter layer CFL. The overcoat layer OC may cover the color filter layer CFL to provide a flat surface over the underlying elements having different levels. The overcoat layer OC may be a colorless light-transmitting layer having no color in the visible light band. For example, the overcoat layer OC may include a colorless light-transmitting organic material such as an acrylic resin and polyimide.

In some embodiments, the overcoat layer OC may further include a dye that can selectively absorb light in a particular wavelength range. The overcoat layer OC can reduce the reflectance of external light by absorbing lights of certain wavelength ranges among lights incident from the outside.

Referring to FIGS. 14 and 15, the cross-sectional structure of a pixel disposed in the folding area FDA of the display panel 100.

Referring to FIGS. 14 and 15, in the folding area FDA of the display panel 100, the via-layer VIA may overlap with the pixel electrode AE including a first portion AEP1 and a second portion AEP2 to be described later. The via-layer VIA may define a groove GRO therein. The groove GRO may have a concave shape in which the surface of the via-layer VIA is recessed toward the substrate SUB. The groove GRO may be disposed in line with the emission area EA or the opening OPE defined by the pixel-defining layer PDL. The area of the groove GRO may be larger than the area of the emission area EA or the area of the opening OPE defined by the pixel-defining layer PDL. The groove GRO may overlap with the concave pixel electrode AE in a plan view, which will be described later.

The groove GRO may include a bottom surface BOS and an inclined surface INS. The bottom surface BOS may be located at the lowest level of the groove GRO, and the inclined surface INS may connect the bottom surface BOS with and the upper surface of the via-layer VIA. The bottom surface BOS may be parallel to the upper surface of the via-layer VIA, and the inclined surface INS may have a gentle slope with respect to the upper surface of the substrate SUB. An inclination angle θ between the inclined surface INS of the groove GRO and the extension line of the bottom surface BOS may be an acute angle. For example, the inclination angle θ may be approximately 10 to 40 degrees.

The pixel electrode AE may be disposed on the via-layer VIA. For example, the pixel electrode AE may be extended from the upper surface of the via-layer VIA onto the groove GRO. The pixel electrode AE may be extended along the bottom surface BOS and the inclined surface INS of the groove GRO. The pixel electrode AE may have a concave shape toward the substrate SUB due to the shape of the groove GRO. Accordingly, the upper surface of the via-layer VIA under the pixel electrode AE may have a shape conforming to the concave upper surface of the pixel electrode AE.

The pixel electrode AE may be the concave pixel electrode AE having a concave upper surface. The pixel electrode AE may include a bottom surface and an inclined surface. For example, the pixel electrode AE may include a first portion AEP1, a second portion AEP2, and a third portion AEP3. The first portion AEP1 may be a bottom disposed on the bottom surface BOS of the groove GRO of the via-layer VIA. The second portion AEP2 may be disposed on the inclined surface INS of the groove GRO of the via-layer VIA and may not overlap with the pixel-defining layer PDL. The third portion AEP3 may be disposed on the upper surface and inclined surface INS of the via-layer VIA and may overlap with the pixel-defining layer PDL in a plan view.

The first portion AEP1 of the pixel electrode AE may be extended in parallel to the substrate SUB along the bottom surface BOS of the groove GRO of the via-layer VIA. For example, the first portion AEP1 of the pixel electrode AE may be extended such that it includes the lowest portion of the pixel electrode AE, e.g., a portion of the pixel electrode AE closest to the substrate SUB. The second portion AEP2 may be extended with a gentle slope with respect to the upper surface of the substrate SUB along the inclined surface INS of the groove GRO of the via-layer VIA. For example, the second portion AEP2 of the pixel electrode AE may be inclined in a direction away from the first portion AEP1. The third portion AEP3 may be extended along the upper surface of the via-layer VIA and the inclined surface INS of the groove GRO. The third portion AEP3 may be covered by the pixel-defining layer PDL.

A light emitting layer OL may be disposed on the pixel electrode AE. The light emitting layer OL may be disposed along the shape of the pixel electrode AE in the emission area EA partitioned by the pixel-defining layer PDL. The common electrode CO may be disposed on the pixel-defining layer PDL and the light emitting layer OL to cover them.

Referring to FIG. 13 in conjunction with FIG. 12, in the pixels arranged in the non-folding area NFA of the display panel 100, the pixel electrode AE is disposed on the flat via-layer VIA, so that most of the light L1 emitted from the light emitting layer OL may be reflected by the pixel electrode AE to exit in the third direction DR1. Since the non-folding area NFA of the display panel 100 is flat with no curved surface, the brightness at the front viewed by the user can be maintained without being lowered.

Referring to FIG. 15 in conjunction with FIG. 12, in the pixels arranged in the folding area FDA of the display panel 100, light emitted from the light emitting layer OL may exit in the third direction DR3 and to the sides. For example, at the first portion AEP1 of the pixel electrode AE, light L2 emitted from the light emitting layer OL may be reflected by the first portion AEP1 and exit in the third direction DR3. At the second portion AEP2 of the pixel electrode AE, as the pixel electrode AE is inclined along the inclined surface INS of the groove GRO, most of the lights L3 emitted from the light emitting layer OL may exit in a direction perpendicular to the second portion AEP2 (e.g., toward a side).

As shown in FIG. 12, since the folding area FDA of the display panel 100 forms a curved surface, the flat pixel electrode AE is also inclined along the curved surface, so that lights exit more toward the sides than toward the front. In contrast, according to the embodiment of the present disclosure, in the pixels disposed in the folding area FDA of the display panel 100, the pixel electrode AE includes a portion having a slope (second portion) in addition to a flat portion (first portion), and accordingly lights emitted from the light emitting layer OL can exit more toward the front of a user. That is to say, by increasing the front brightness in the folding area FDA of the display panel 100, it is possible to reduce the brightness difference between the folding area FDA and the non-folding area NFA.

Hereinafter, a display device according to other embodiments of the present disclosure will be described with reference to other drawings.

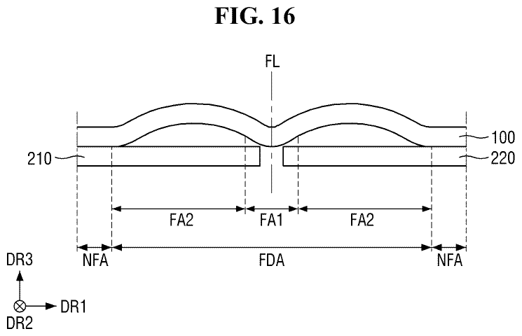

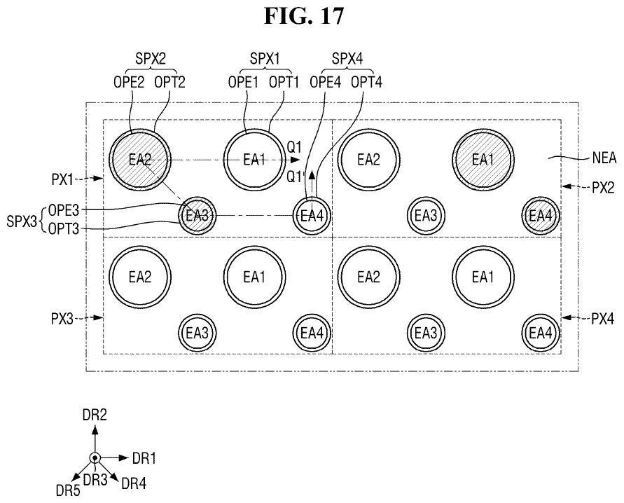

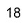

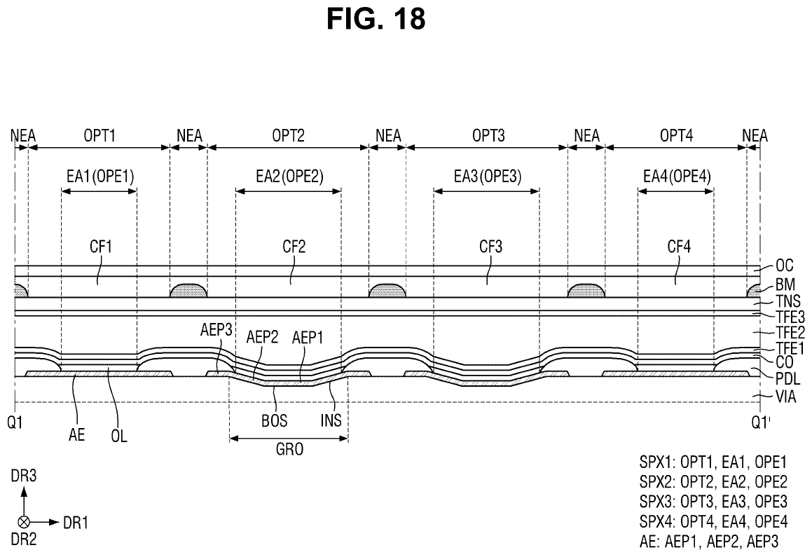

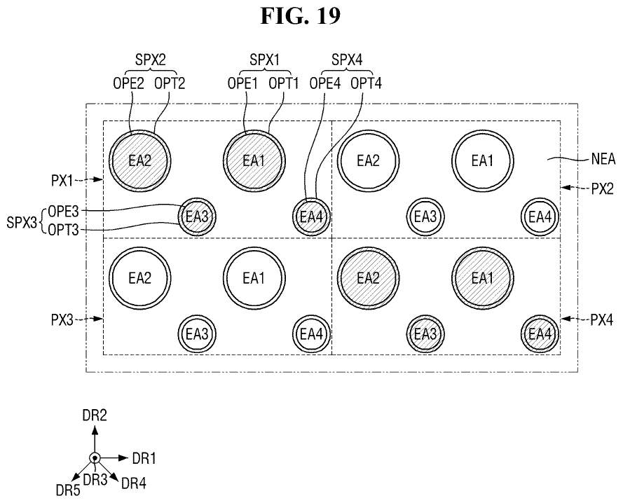

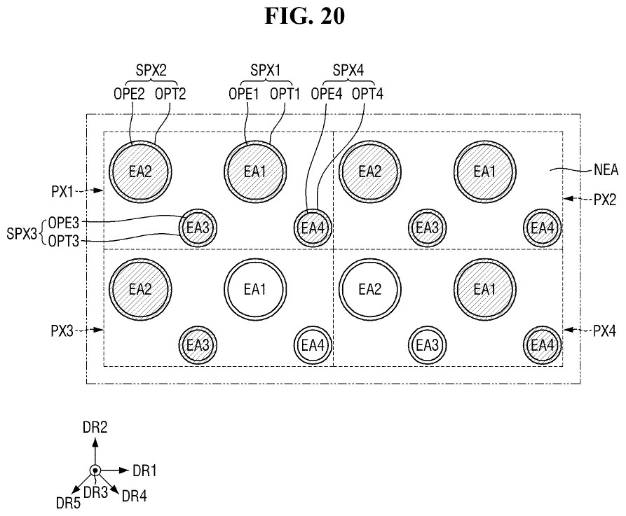

FIG. 16 is a cross-sectional view schematically showing a folding area of a display device according to an embodiment of the present disclosure. FIG. 17 is a plan view showing an example of pixels in a folding area of a display device according to an embodiment of the present disclosure. FIG. 18 is a cross-sectional view taken along line Q1-Q1′ of FIG. 17. FIG. 19 is a plan view showing another example of pixels of a folding area of a display device according to an embodiment of the present disclosure. FIG. 20 is a plan view showing another example of pixels in a folding area of a display device according to an embodiment of the present disclosure.

The embodiment of FIGS. 16 to 20 is different from the above-described embodiment of FIGS. 14 and 15 in that a folding area FDA is divided into a first folding area FA1 and a second folding area FA2, and the numbers of pixels are different between the first folding area FA1 and the second folding area FA2. Therefore, the following description will focus on the difference and the redundant description will be omitted.

Referring to FIG. 16, a display panel 100 of a display device 10 may include a folding area FDA. In the folding area FDA, the display panel 100 may include a first folding area FA1 with a relatively small decrease in brightness, and a second folding area FA2 with a relatively large curvature of a curved surface.

The first folding area FA1 may include the folding axis FL and may have a width of πR/8 to πR/4 from each side of the folding axis FL to the folding axis FL in a direction (i.e., the first direction DR1) perpendicular to the folding axis FL. For example, the first folding area FA1 may be extended from the folding axis FL by πR/8 to πR/4 on the first side of the first direction DR1, and may be extended from the folding axis FL by πR/8 to πR/4 on the second side of the first direction DR1. Accordingly, the total width of the first folding area FA1 in the first direction DR1 may range from πR/4 to πR/2.

The second folding area FA2 may refer to the other areas of the folding area FDA than the first folding area FA1. For example, the second folding area FA2 may include an area on the first side of the first folding area FA1 in the first direction DR1, and an area on the second side of the first folding area FA1 in the first direction DR1.

According to the embodiment of the present disclosure, the number of concave pixel electrodes AE in a pixel group including four pixels SPXn among the pixel groups PX1, PX2, PX3 and PX4 arranged in the second folding area FA2 may be greater than the number of concave pixel electrodes AE in a pixel group including four pixels SPXn among the pixel groups PX1, PX2, PX3 and PX4 arranged in the first folding area FA1.

Referring to FIGS. 17 and 18, a plurality of pixel groups PX1, PX2, PX3 and PX4 arranged in the first folding area FA1 are shown.

The plurality of pixel groups PX1, PX2, PX3 and PX4 may include first to fourth pixel groups PX1 to PX4. The first pixel group PX1 and the second pixel group PX2 may be arranged adjacent to each other in the first direction DR1, the third pixel group PX3 may be arranged adjacent to the first pixel group PX1 in the opposite direction of the second direction DR2, and the fourth pixel group PX4 may be arranged adjacent to the third pixel group PX3 in the first direction DR1.

Each pixel group PX may include first to fourth pixels SPX1 to SPX4. The first pixel SPX1 and the second pixel SPX2 may be arranged adjacent to each other in the first direction DR1, the third pixel SPX3 may be arranged adjacent to the second pixel SPX2 in the fourth direction DR4, and the fourth pixel SPX4 may be arranged adjacent to the third pixel SPX3 in the first direction DR1. The first pixel SPX1 may emit red light, the second pixel SPX2 may emit blue light, and the third pixel SPX3 and the fourth pixel SPX4 may emit green light. It is, however, to be understood that the present disclosure is not limited thereto. For another example, each pixel group PX may include one first pixel SPX1, one second pixel SPX2, and two third pixels SPX3.

According to this embodiment, 20% to 30% of the pixels SPXn of the four pixel groups PXn may include the concave pixel electrodes AE. For example, among the total of sixteen pixels SPXn in the first to fourth pixel groups PX1 to PX4, four pixels SPXn may include concave pixel electrodes AE. For example, the second pixel SPX2 and the third pixel SPX3 of the first pixel group PX1, and the first pixel SPX1 and the fourth pixel SPX4 of the second pixel group PX2 may include concave pixel electrodes AE, respectively. Herein, the number of pixels SPXn corresponding to 20% to 30% of the total number of pixels SPXn of the four pixel groups PXn may mean the natural number of pixels SPXn between 20% and 30%. For example, the natural number that exists between 20% and 30% of the total 16 pixels SPXn is four. Therefore, four pixels SPXn may have the concave pixel electrodes AE.

Since the concave pixel electrode AE is formed in two pixels SPXn in each of the first pixel group PX1 and the second pixel group PX2, the cross-section of the first pixel group PX1 will be described as an example.

Referring to FIG. 18, no groove GRO is defined in the flat via-layer VIA of each of the first pixel SPX1 and the fourth pixel SPX4, and the pixel electrode AE may also be flat. On the other hand, a groove GRO may be defined in the via-layer VIA of each of the second pixel SPX2 and the third pixel SPX3, and the pixel electrode AE may be formed as a concave pixel electrode.

The second pixel SPX2 will be described as an example. The via-layer VIA of the second pixel SPX2 may define a groove GRO therein. The groove GRO may include a bottom surface BOS and an inclined surface INS. The bottom surface BOS may be parallel to the upper surface of the via-layer VIA, and the inclined surface INS may have a gentle slope with respect to the upper surface of the substrate SUB.

The pixel electrode AE may be disposed on the via-layer VIA and may be extended along the bottom surface BOS and the inclined surface INS of the groove GRO. The pixel electrode AE may be a concave pixel electrode that includes a first portion AEP1, a second portion AEP2, and a third portion AEP3. The first portion AEP1 may be disposed on the bottom surface BOS of the groove GRO of the via-layer VIA, the second portion AEP2 may be disposed on the inclined surface INS of the groove GRO of the via-layer VIA, and the third portion AEP3 may be disposed on the upper surface of the via-layer VIA.

The light emitting layer OL may be disposed on the pixel electrode AE. The light emitting layer OL may be disposed along the shape of the pixel electrode AE in the emission area EA partitioned by the pixel-defining layer PDL. The common electrode CO may be disposed on the pixel-defining layer PDL and the light emitting layer OL to cover them.

At the first portion AEP1 of the pixel electrode AE, the light emitted from the light emitting layer OL may be reflected by the first portion AEP1 and travel in the third direction DR3. At the second portion AEP2 of the pixel electrode AE, as the pixel electrode AE is inclined along the inclined surface INS of the groove GRO, most of the lights emitted from the light emitting layer OL may travel in a direction perpendicular to the second portion AEP2 (e.g., toward a side).

As a result, in the second pixel SPX2 and the third pixel SPX3, the pixel electrode AE is formed to include not only a flat portion (the first portion) but also a sloped portion (the second portion), so that the lights emitted from the light emitting layer OL may exit more toward the front of a user. That is to say, the front brightness can be increased in the first folding area FA1 of the folding area FDA of the display panel 100.

FIG. 19 shows a plurality of pixel groups PX1, PX2, PX3 and PX4 arranged in the second folding area FA2.

Since the second folding area FA2 has a lower front brightness than the first folding area FA1, more pixels SPXn may include the concave pixel electrodes AE in order to increase the front brightness. According to this embodiment, 45% to 55% of the pixels SPXn of the four pixel groups PX1, PX2, PX3 and PX4 may include the concave pixel electrodes AE. For example, in the second folding area FA2, eight pixels SPXn among the first to fourth pixel groups PX1 to PX4 may include concave pixel electrodes AE. For example, the first to fourth pixels SPX1 to SPX4 of the first pixel group PX1 and the first to fourth pixels SPX1 to SPX4 of the fourth pixel group PX4 may include concave pixel electrodes AE, respectively. The pixels SPXn having the concave pixel electrodes AE formed therein among the four pixel groups PX may be arranged adjacent to each other in the fourth direction DR4. For example, the pixels SPXn having the concave pixel electrodes AE formed therein may be arranged symmetrically to each other so that the portions where lights exit are not closer to any side in the four pixel groups PX.

As a result, more pixels SPXn include the concave pixel electrodes AE in the second folding area FA2 than in the first folding area FA1, so that the lights emitted from the light emitting layer OL can exit more toward the front (i.e., the third direction DR3) of the user. Accordingly, it is possible to further reduce the brightness difference between the first folding area FA1 and the second folding area FA2.

Referring to FIG. 20, since the second folding area FA2 has a lower front brightness than the first folding area FA1, more pixels SPXn may include the concave pixel electrodes AE in order to increase the front brightness (i.e., bright in the third direction DR3).

According to this embodiment, 70% to 80% of the pixels SPXn of the four pixel groups PX1, PX2, PX3 and PX4 may include the concave pixel electrodes AE. For example, in the second folding area FA2, twelve pixels SPXn among the first to fourth pixel groups PX1 to PX4 may include concave pixel electrodes AE. For example, first to fourth pixels SPX1 to SPX4 of each of the first pixel group PX1 and the second pixel group PX2, second and third pixels SPX2 and SPX3 of the third pixel group PX3, and first and fourth pixels SPX1 and SPX4 of the fourth pixel group PX4 may include concave pixel electrodes AE.

The pixels SPXn having the concave pixel electrodes AE formed therein among the four pixel groups PX1, PX2, PX3 and PX4 may be arranged symmetrically to each other. For example, the pixels SPXn in which the concave pixel electrodes AE are formed may be arranged symmetrically to each other based on an imaginary line traversing between the first pixel group PX1 and the second pixel group PX2 in the second direction DR2.

According to this embodiment of the present disclosure, the number of pixels SPXn having the structure including the concave pixel electrodes AE in four pixel groups PX1, PX2, PX3 and PX4 among the pixel groups arranged in the second folding area FA2 may be greater than the number of pixels SPXn having the structure including the concave pixel electrodes AE in four pixel groups PX1, PX2, PX3 and PX4 among the pixels SPXn arranged in the first folding area FA1.

When concave pixel electrodes AE are disposed in four pixels SPXn in four pixel groups PX1, PX2, PX3 and PX4 in the first folding area FA1 as shown in FIG. 17, concave pixel electrodes AE may be disposed in eight or twelve pixels SPXn in the second folding area FA2 as shown in FIG. 19 or 20. According to another embodiment, when concave pixel electrodes AE are disposed in eight pixels SPXn in four pixel groups PX1, PX2, PX3 and PX4 in the first folding area FA1 as shown in FIG. 19, concave pixel electrodes AE may be disposed in twelve pixels SPXn in the second folding area FA2 as shown in FIG. 20. According to still another embodiment, when concave pixel electrodes AE are disposed in twelve pixels SPXn in four pixel groups PX1, PX2, PX3 and PX4 in the first folding area FA1 as shown in FIG. 20, concave pixel electrodes AE may be disposed in sixteen pixels SPXn in the second folding area FA2.

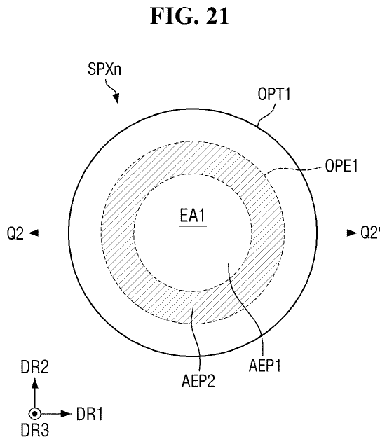

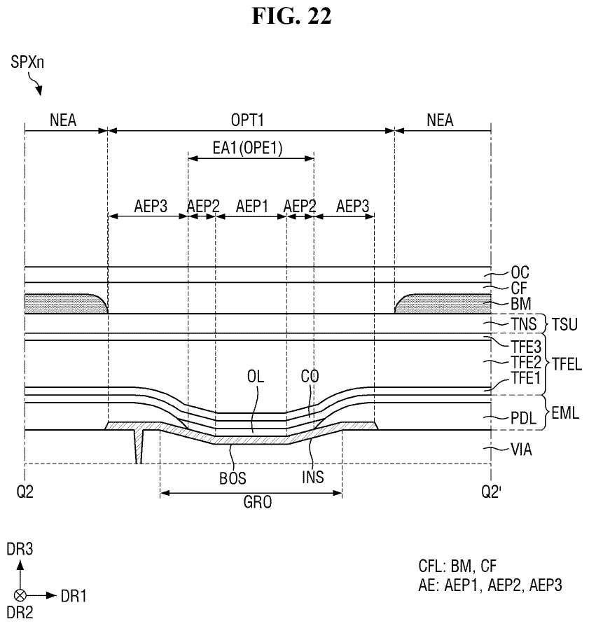

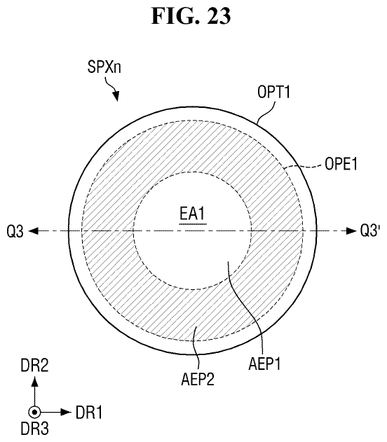

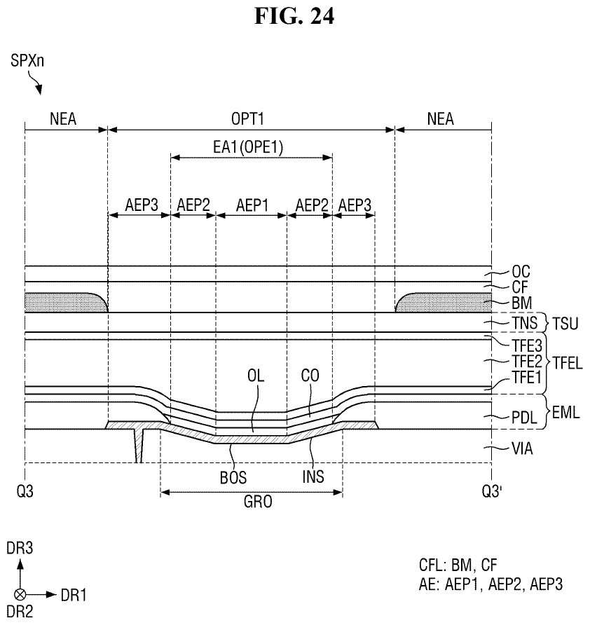

FIG. 21 is a plan view showing a pixel of a first folding area of a display device according to an embodiment of the present disclosure. FIG. 22 is a cross-sectional view taken along line Q2-Q2′ of FIG. 21. FIG. 23 is a plan view showing a pixel of a second folding area of a display device according to an embodiment of the present disclosure. FIG. 24 is a cross-sectional view taken along line Q3-Q3′ of FIG. 23.

According to the embodiment of FIGS. 21 to 24, pixels SPXn of a first folding area FA1 and a second folding area FA2, which are bendable portions, include concave pixel electrodes AE, and second portion of the pixel electrodes AE have different areas. The following description will focus on the difference and the redundant description will be omitted.

FIGS. 21 and 22 show a pixel SPXn disposed in the first folding area FA1, while FIGS. 23 and 24 show a pixel SPXn disposed in the second folding area FA2.

The pixel electrode AE may be a concave pixel electrode that includes a first portion AEP1, a second portion AEP2, and a third portion AEP3. The first portion AEP1 may be disposed on the bottom surface BOS of the groove GRO of the via-layer VIA. The second portion AEP2 may be disposed on the inclined surface INS of the groove GRO of the via-layer VIA and may not overlap with the pixel-defining layer PDL in a plan view. The third portion AEP3 may be disposed on the upper surface and inclined surface INS of the via-layer VIA and may overlap with the pixel-defining layer PDL in a plan view.

Lights may be emitted substantially from the light emitting layer OL on the first portion AEP1 and the second portion AEP2 of the pixel electrode AE, and the lights exit upward. At the first portion AEP1, most of the lights emitted from the light emitting layer OL may exit in the third direction DR3 (e.g., toward the front). At the second portion AEP2, most of the lights emitted from the light emitting layer OL may exit in a direction perpendicular to the second portion AEP2 (e.g., toward a side).

A first area of the second portion AEP2 of the pixel electrode AE in the pixel SPXn disposed in the first folding area FA1 may be different from a second area of the second portion AEP2 of the pixel electrode AE of the pixel SPXn disposed in the second folding area FA2. For example, the first area of the second portion AEP2 of the pixel electrode AE in the pixel SPXn disposed in the first folding area FA1 may be smaller than the second area of the second portion AEP2 of the pixel electrode AE of the pixel SPXn disposed in the second folding area FA2. The amount of light exiting toward the side increases as the area of the second portion AEP2 of the pixel electrode AE increases, and the amount of light exiting toward the side decreases as the area of the second portion AEP2 of the pixel electrode AE decreases.

Since the front brightness of the second folding area FA2 is lower than the front brightness of the first folding area FA1, the second area of the second portion AEP2 of the pixel electrode AE is formed to be larger than the first area of the first folding area FA1, so that the brightness on the sides of the pixels SPXn (the front to a user) can be increased. Accordingly, it is possible to reduce the brightness difference between the first folding area FA1 and the second folding area FA2, and to improve the brightness difference between the folding area FDA and the non-folding area NFA as well.

According to another embodiment, the first area of the inclined surface INS of the pixel electrode AE in the pixel SPXn disposed in the first folding area FA1 may be different from the second area of the inclined surface INS of the pixel electrode AE of the pixel SPXn disposed in the second folding area FA2.

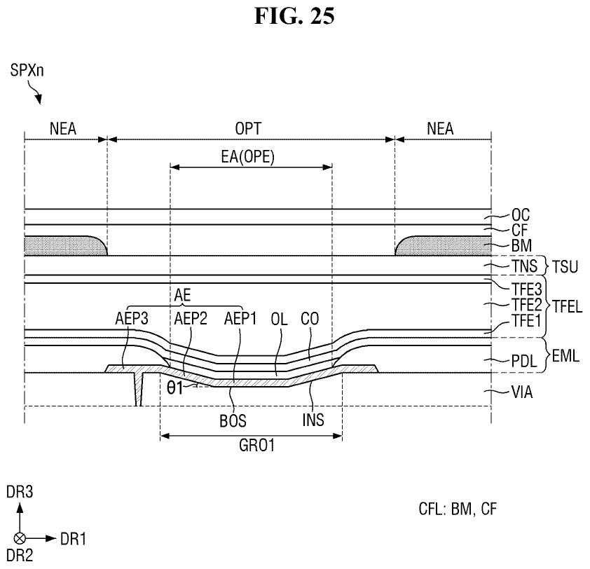

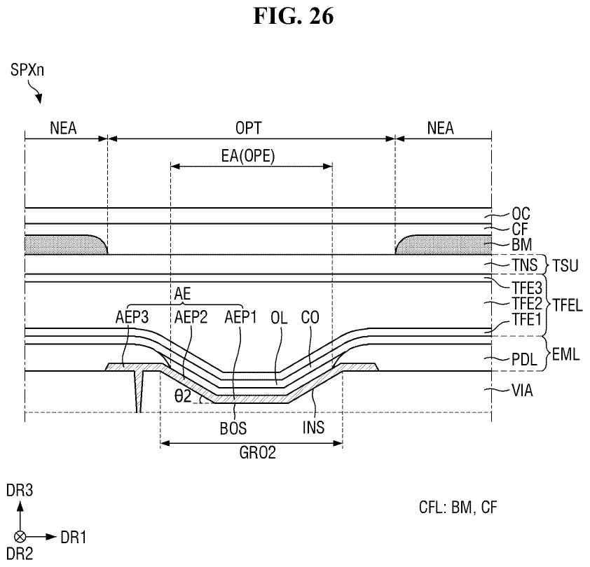

FIG. 25 is a cross-sectional view showing a pixel of a first folding area of a display device according to an embodiment of the present disclosure. FIG. 26 is a cross-sectional view showing a pixel of a second folding area of a display device according to an embodiment of the present disclosure.

The embodiment of FIGS. 25 and 26 is different from the above-described embodiments in that a via-layer VIA of each of pixels SPXn in a first folding area FA1 and a second folding area FA2 defines a groove GRO (e.g., GRO1, GRO2) therein, and an angle between an extended line of a bottom surface BOS and an inclined surface INS of the groove GRO is different between the first folding area FA1 and the second folding area FA2. Therefore, the following description will focus on the difference and the redundant description will be omitted.

FIG. 25 shows a pixel SPXn disposed in the first folding area FA1. FIG. 26 shows a pixel SPXn disposed in the second folding area FA2.

Each of grooves GRO1 and GRO2 may include a bottom surface BOS and an inclined surface INS. The angles θ1 and θ2 between the inclined surfaces INS and the extension lines of the bottom surfaces BOS of the grooves GRO1 and GRO2, respectively, may be acute angles. For example, the angles θ1 and θ2 may each range approximately from 10 to 40 degrees.

The pixel electrode AE may include a first portion AEP1, a second portion AEP2, and a third portion AEP3. The first portion AEP1 may be disposed on the bottom surface BOS of each of the grooves GRO1 and GRO2 of the via-layer VIA. The second portion AEP2 may be disposed on the inclined surface INS of each of the grooves GRO1 and GRO2 of the via-layer VIA and may not overlap with the pixel-defining layer PDL in a plan view. The third portion AEP3 may be disposed on the upper surface and inclined surface INS of the via-layer VIA and may overlap with the pixel-defining layer PDL in a plan view. At the second portion AEP2 of the pixel electrode AE, most of the lights emitted from the light emitting layer OL may exit in a direction perpendicular to a major surface of the second portion AEP2 (e.g., inclined direction with respect to the third direction DR3).

The grooves GRO1 and GRO2 may include a first groove GRO1 located in the first folding area FA1, and a second groove GRO2 located in the second folding area FA2. A first inclination angle θ1 between the inclined surface INS and the extension line of the bottom surface BOS of the first groove GRO1 in the pixels SPXn disposed in the first folding area FA1 may be different from a second inclination angle θ2 between the inclined surface INS and the extension line of the bottom surface BOS of the second groove GRO2 of the second folding area FA2. For example, the first inclination angle θ1 between the inclined surface INS and the extension line of the bottom surface BOS of the first groove GRO1 in the pixels SPXn disposed in the first folding area FA1 may be smaller than the second inclination angle θ2 between the inclined surface INS and the extension line of the bottom surface BOS of the second groove GRO2 of the second folding area FA2. As the inclination angle between the inclined surface INS and the extension line of the bottom surface BOS of each of the grooves GRO1 and GRO2 increases, the second portion AEP2 of the pixel electrode AE is inclined toward the side, so that the amount of lights exiting toward the side may increase. On the contrary, as the inclination angle between the inclined surface INS and the extension line of the bottom surface BOS of each of the grooves GRO1 and GRO2 decreases, the second portion AEP2 of the pixel electrode AE is less inclined toward the side, so that the amount of lights exiting toward the side may decrease.

Since the front brightness of the second folding area FA2 is lower than the front brightness of the first folding area FA1, by forming the second inclination angle θ2 between the inclined surface INS and the extension line of the bottom surface BOS of the second groove GRO2 larger than the first inclination angle θ1 of the first folding area FA1, it is possible to increase the brightness on the sides of the pixels SPXn (the front of a user). Accordingly, it is possible to reduce the brightness difference between the first folding area FA1 and the second folding area FA2, and to improve the brightness difference between the folding area FDA and the non-folding area NFA as well.

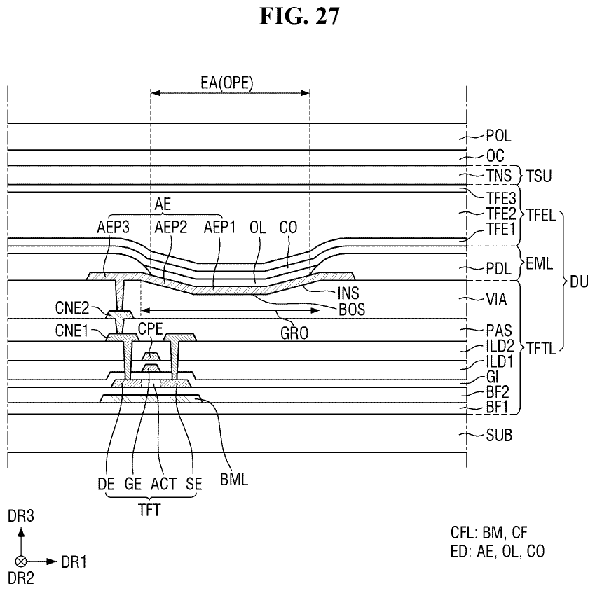

FIG. 27 is a cross-sectional view schematically showing a display device according to yet another embodiment.

FIG. 27 shows an example where the color filter layer CFL is eliminated from the example of FIG. 14 and a polarizing member POL is disposed.

Referring to FIG. 27, an overcoat layer OC may be disposed on a touch sensing layer TSU, and a polarizing member POL may be disposed on the overcoat layer OC. The overcoat layer OC may provide a flat surface over the touch sensing layer TSU so that the polarizing member POL can be attached reliably. The polarization member POL may change the polarization axis of light incident from the outside to block the transmission of light reflected at the display layer DU to exit, thereby prevent reflection of external light. The polarization member POL may function as an anti-reflection layer.

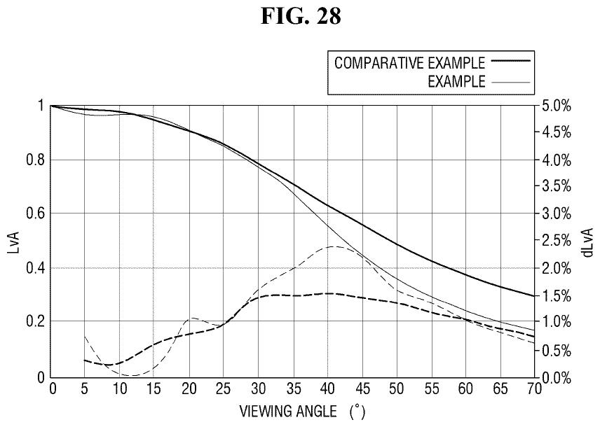

FIG. 28 is a graph showing brightness and the amount of changes in the brightness versus viewing angle of display devices according to Comparative Example and Example.

In FIG. 28, a display device according to Comparative Example has the structure of FIG. 13 in which no groove is formed in the via-layer of the pixels, while a display device according to Example has the structure of FIG. 14 in which the groove is formed in the via-layer of the pixels. In Example, the groove forms the inclination angle between the extension of the bottom surface and the inclined surface was 20 degrees.

With respect to the front of the display devices according to Comparative Example and Example, brightness (LvA) at the viewing angle of 45 degrees, maximum brightness change (dLvA) by changing the viewing angle by one degree, and viewing angle color shift (VACS) values were measured and shown in Table 1 below. In addition, the brightness and the maximum brightness change versus the viewing angle of the display devices according to Comparative Example and Example are shown in the graph of FIG. 28. In the graph of FIG. 28, the solid lines represent the brightness on the left vertical axis, and the dotted lines represent the maximum brightness change on the right vertical axis.

TABLE 1

| / | | Comparative Example | | | Example | | |
|---|---|---|---|---|---|---|---|
| Brightness | | 44.62 | | | 56.04 | | |
| Brightness Change | | 2.39 | | | 1.54 | | |
| (dLvA, Max) | | | | | | | |
| VACS | Angle (°) | 0~15 | 15~30 | 30~45 | 0~15 | 15~30 | 30~45 |
| | Value | 6.3 | 9.0 | 4.4 | 3.5 | 5.7 | 3.0 |

Referring to Table 1 and FIG. 28, compared to Comparative Example, the brightness of the display device according to Example was increased by approximately 11.42% at the viewing angle of 45°, and the maximum brightness change was decreased by approximately 0.85%.

It can be seen from the above that the side viewing angle characteristics of the display device in which grooves are formed in the via-layer were improved.

In addition, compared to Comparative Example, the viewing angle color shift values of the display device according to Example decreased in the viewing angle range.

It can be seen from the above that color differences depending on the viewing angle were reduced in the display device with the grooves formed in the via-layer.

It can be seen from the above results that it is possible to reduce the brightness difference due to the curved surface of the folding area by employing the pixel structure according to the embodiments to the folding area of the display panel.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. A display device comprising:
a substrate having a folding area foldable with a radius of curvature over a folding axis, and a non-folding area extended from the folding area; and
pixels disposed in each of the folding area and the non-folding area on the substrate,
wherein each of the pixels comprises:
a pixel electrode;
a light emitting layer disposed on the pixel electrode; and
a common electrode disposed on the light emitting layer, and
wherein the pixel electrode in at least one of the pixels disposed in the folding area is a concave pixel electrode comprising a first portion, which is a bottom portion of the pixel electrode, and a second portion, which is extended from the first portion and inclined in a direction away from the substrate.

2. The display device of claim 1, wherein the folding area has a width of 0.75πR to 1.25πR from each side of the folding axis to the folding axis in a direction perpendicular to the folding axis, and R is the radius of curvature in an unfolded state of the folding area.

3. The display device of claim 1, further comprising:
a via-layer disposed between the substrate and the pixel electrode,
wherein the via-layer defines a groove therein overlapping the concave pixel electrode, and
wherein the groove comprises a bottom surface and an inclined surface inclined with respect to the bottom surface.

4. The display device of claim 3, wherein the groove comprises
a first groove located at a portion of the folding area, an extension of the bottom surface and the inclined surface of which form a first inclination angle, and
a second groove located at another portion of the folding area, an extension line of the bottom surface and the inclined surface of which form a second inclination angle, and
wherein the first inclination angle and the second inclination angle are different from each other.

5. The display device of claim 3, wherein an inclination angle between an extension line of the bottom surface and the inclined surface ranges from 10 to 40 degrees.

6. The display device of claim 3, wherein each of the pixels further comprises: a pixel-defining layer covering an edge of the pixel electrode, and
wherein the first portion of the concave pixel electrode is disposed on the bottom surface of the groove, and the second portion of the concave pixel electrode is disposed on the inclined surface of the groove and does not overlap the pixel-defining layer in a plan view.

7. The display device of claim 6, wherein the concave pixel electrode further comprises: a third portion disposed on an upper surface of the via-layer and the inclined surface of the groove and overlapping with the pixel-defining layer in the plan view.

8. The display device of claim 6, wherein an area of the second portion of the concave pixel electrode disposed in a portion of the folding area is different from an area of the second portion of the concave pixel electrode disposed in another portion of the folding area in the plan view.

9. The display device of claim 3, wherein the via-layer defines the groove in the folding area but not in the non-folding area.

10. The display device of claim 1, wherein the folding area comprises a first folding area having a width of πR/8 to πR/4 from each side of the folding axis to the folding axis in a direction perpendicular to the folding axis, and a second folding area other than the first folding area, and R is the radius of curvature in an unfolded state of the folding area, and
wherein a total number of concave pixel electrodes disposed in the second folding area is greater than a total number of concave pixel electrodes disposed in the first folding area.

11. The display device of claim 10, wherein the pixels comprise first to third pixels, which emit lights of different colors from each other,
wherein one first pixel, one second pixel and two third pixels form a pixel group, and
wherein a total number of pixels having the concave pixel electrodes included in four pixel groups in the first folding area is equal to 20% to 40% of a total number of pixels included in the four pixel groups.

12. The display device of claim 10, wherein the pixels comprise first to third pixels, which emit lights of different colors from each other,
wherein one first pixel, one second pixel and two third pixels form a pixel group, and
wherein a total number of pixels having the concave pixel electrodes included in four pixel groups in the second folding area is equal to 45% to 55% of a total number of pixels included in the four pixel groups.

13. The display device of claim 10, wherein the pixels comprise first to third pixels, which emit lights of different colors,
wherein one first pixel, one second pixel and two third pixels form a pixel group, and
wherein a total number of pixels having the concave pixel electrodes included in four pixel groups in the second folding area is equal to 70% to 80% of a total number of pixels included in the four pixel groups.

14. The display device of claim 1, further comprising:
an anti-reflection layer disposed on the common electrode, wherein the anti-reflection layer is a color filter layer or a polarizing member.

15. The display device of claim 4, wherein the folding area comprises: a first folding area having a width of πR/8 to πR/4 from each side of the folding axis to the folding axis in a direction perpendicular to the folding axis, where R is the radius of curvature in an unfolded state of the folding area; and a second folding area other than the first folding area,
wherein the first groove is located in the first folding area, and the second groove is located in the second folding area, and
wherein the first inclination angle is smaller than the second inclination angle.

16. The display device of claim 6, wherein the folding area comprises: a first folding area having a width of πR/8 to πR/4 from each side of the folding axis to the folding axis in a direction perpendicular to the folding axis, where R is the radius of curvature in an unfolded state of the folding area; and a second folding area other than the first folding area,
wherein the second portion of the concave pixel electrode disposed in the first folding area has a first area, and the second portion of the concave pixel electrode disposed in the second folding area has a second area in the plan view, and
wherein the first area is smaller than the second area.

17. A display device switchable between a folded state and an unfolded state over a folding axis, the display device comprising:
a substrate having a bendable portion, which is bent in the folded state, and a flat portion, which is extended from the bendable portion and is flat in the folded state;
an insulating layer disposed on the substrate;
pixel electrodes disposed on the insulating layer;
a pixel-defining layer disposed on the pixel electrodes and defining openings associated with the pixel electrodes, respectively;
light emitting layers arranged to overlap with the openings on the pixel electrodes; and
a counter electrode disposed on the light emitting layers,
wherein the pixel electrodes comprise a first pixel electrode disposed in the bendable portion and a second pixel electrode disposed in the flat portion, and
wherein the first pixel electrode has a concave upper surface toward the substrate.

18. The display device of claim 17, wherein an upper surface of the insulating layer has a shape conforming to the concave upper surface of the first pixel electrode.

19. The display device of claim 17, wherein the concave upper surface of the first pixel electrode comprises a bottom surface and an inclined surface, and
wherein a first inclination angle between the bottom surface and the inclined surface of the first pixel electrode located in an area of the bendable portion is different from a second inclination angle between the bottom surface and the inclined surface of the first pixel electrode located in another area of the bendable portion.

20. The display device of claim 17, wherein the concave upper surface of the first pixel electrode comprises a bottom surface and an inclined surface, and
wherein an area of the inclined surface of the first pixel electrode located at a position of the bendable portion in a plan view is different from an area of the inclined surface of the first pixel electrode located in another position of the bendable portion in the plan view.
